(19) United States
(12) Patent Application Publication
(10) Pub. No.: US 2026/0106432 A1
(43) Pub. Date: Apr. 16, 2026

(54) SEMICONDUCTOR OPTICAL INTEGRATED DEVICE, METHOD FOR DRIVING SEMICONDUCTOR OPTICAL INTEGRATED DEVICE, OPTICAL MODULE, MULTI-LEVEL INTENSITY MODULATION TRANSCEIVER, AND OPTICAL LINE TERMINATING DEVICE

(71) Applicant: Mitsubishi Electric Corporation, Tokyo (JP)

(72) Inventors: Kyosuke KURAMOTO, Tokyo (JP); Eitaro ISHIMURA, Tokyo (JP)

(73) Assignee: Mitsubishi Electric Corporation, Tokyo (JP)

(21) Appl. No.: 19/315,461

(22) Filed: Aug. 29, 2025

(30) Foreign Application Priority Data
Oct. 11, 2024 (JP) 2024-178785

(51) Int. Cl. H01S 5/026; H01S 5/02345; H01S 5/20; H04B 10/40

(52) U.S. Cl. CPC H01S 5/0265; H01S 5/02345; H01S 5/2018; H04B 10/40

(57) ABSTRACT

A semiconductor optical integrated device of the present disclosure includes: a substrate; a first EA modulator section formed on the substrate and comprising at least an n-type first semiconductor layer, a first modulation layer, and a p-type first semiconductor layer; and a second EA modulator section formed on the substrate and comprising at least an n-type second semiconductor layer, a second modulation layer having a width smaller than a width of the first modulation layer, and a p-type second semiconductor layer electrically connected to the n-type first semiconductor layer.

### BACKGROUND OF THE DISCLOSURE

### 1. Field of the Disclosure

The present disclosure relates to a semiconductor optical integrated device, a method for driving a semiconductor optical integrated device, an optical module, a multi-level intensity modulation transceiver, and an optical line terminating device.

### 2. DESCRIPTION OF THE BACKGROUND ART

Along with the progress of digital transformation utilizing digital information, the development of communication networks for exchanging digital information and data centers for storing and processing data has been remarkable. Optical communication is used for communication networks and data center communications, and remarkable progress has been made in recent years in terms of high-speed and high-capacity communication.

In communication networks and data centers, on the transmitting side of optical communication, an EA modulator integrated semiconductor laser (EML), which is a kind of an optical modulator integrated semiconductor laser, is used as a light source. The EA modulator integrated semiconductor laser is a device that integrates an electro-absorption (EA) modulator, which excels in high-speed performance, and a laser diode (LD) on a single chip.

In the EA modulator integrated semiconductor laser, laser light emitted from the semiconductor laser is modulated by the EA modulator, by extinguishing (absorbing) or transmitting the light so as to correspond to the digital signals zero and one. The laser light modulated by the EA modulator enables high-speed modulation compared to the method of directly modulating the current of the semiconductor laser, and also enables long-distance transmission because the wavelength spectrum spread during optical modulation is small. Note that the EA modulator integrated semiconductor laser is an example of a semiconductor optical integrated device.

In recent years, the EA modulator integrated semiconductor laser has become the most important optical device for high-speed communication over 25 Gbit/sec. In particular, high symbol rate optical transmission exceeding 50 Gbaud is carried out using the PAM4 (Pulse Amplitude Modulation four-level) system in data centers. Note that one Gbaud means one billion pulses per one second.

In the EA modulator, multiple quantum well layers (MQWs) are mainly used as layers (hereinafter, referred to as modulation layer) that modulate light intensity by absorption of light. When an electric field is applied to an MQW layer, which is an i-type layer, by applying a reverse voltage to a p-i-n junction sandwiched between a p-type semiconductor layer and an n-type semiconductor layer, the wavelength of the light absorption edge of the MQW layer shifts toward a longer wavelength. This phenomenon is called the quantum-confined Stark effect. The phenomenon of the optical absorption coefficient changing due to the shift in the wavelength of the light absorption edge caused by the application of an electric field is used to modulate the light (see, for example, Non-Patent Document 1).
Patent Document 1: Japanese U.S. Pat. No. 4,698,888
Patent Document 2: Japanese U.S. Pat. No. 4,017,352
Patent Document 3: Japanese U.S. Pat. No. 3,591,447
Patent Document 4: Japanese U.S. Pat. No. 5,573,386
Non-Patent Document 1: THOMAS H. WOOD, “Multiple Quantum Well (MQW) Waveguide Modulators,” JOURNAL OF LIGHTWAVE TECHNOLOGY, VOL. 6, NO. 6, pp. 743-757 (1988)

Problems related to electromagnetic interference in EA modulator integrated semiconductor lasers will be explained below. For example, in the EA modulator integrated semiconductor laser used in the PAM4 transceiver, DC current of about +100 mA is supplied to the semiconductor laser, and DC bias voltage of about −1 V and signal voltage of 1 Vpp (Peak to Peak Voltage) are applied to the EA modulator for driving.

In the PAM4 transceiver, multiple EA modulator integrated semiconductor lasers with different laser wavelengths are mounted close to each other to perform wavelength multiplexed communication. In recent years, in order to respond to the demand for miniaturization of transceivers, a configuration has been required in which multiple EA modulator integrated semiconductor lasers are mounted in parallel at a narrow pitch of about 1 mm, for example, four or more EA modulator integrated semiconductor lasers are mounted at a pitch of about 1 mm.

Meanwhile, in order to respond to high-capacity communication, a voltage modulation signal with a modulation speed of 50 Gbaud or more is applied to the EA modulator as described above. The high-frequency modulation signal applied to the EA modulator integrated semiconductor laser is applied to the EA modulator through a power line including signal lines, wires, etc., and electromagnetic waves are radiated in this process. The semiconductor laser is electrically connected to the LD current line through wires, etc., but the wires are particularly susceptible to electromagnetic interference. When the semiconductor laser is affected by electromagnetic interference, there is a problem that the laser light intensity is modulated at high frequencies, causing intensity noise.

In addition, when electromagnetic waves generated from adjacent EA modulator integrated semiconductor lasers are coupled to the EA modulator, potential blur due to electromagnetic interference occurs and the trace line of the electric modulation waveform becomes thick. As a result, there is a problem that the quality of the optical waveform deteriorates and the error rate increases. In addition, there is a problem that electromagnetic interference occurs with adjacent EA modulator drivers and with photodetectors.

In the future, as generative AI develops, the amount of data center communication processing is expected to increase even further, and it is expected that many transceivers will be used. However, as the bandwidth increases, the amount of electromagnetic interference also increases, and due to the influence of the electromagnetic interference described above, there are now limits to the high-density mounting and broadband communication speeds of EA modulator integrated semiconductor lasers, and solving the problems caused by electromagnetic interference has become a major issue. Currently, higher speeds of 100 to 200 Gbaud or more are also required for EA modulator integrated semiconductor lasers. However, in this case, the cutoff frequency of the EA modulator needs to be 100 GHz or more, resulting in an increasing trend in the influence of electromagnetic interference. In addition, further improvements in the extinction ratio, the wavelength chirp, and the modulation bandwidth of EA modulator integrated semiconductor lasers are also necessary.

### SUMMARY OF THE DISCLOSURE

The present disclosure has been made to solve the above problems, and an object of the present disclosure is to achieve high-density multi-element mounting of semiconductor optical integrated devices and large-capacity communication by reduction of electromagnetic interference of the semiconductor optical integrated device and improving device characteristics such as extinction ratio, wavelength chirp, and modulation bandwidth, and to achieve a method for driving a semiconductor optical integrated device capable of improving device characteristics.

A method for driving a semiconductor optical integrated device according to the present disclosure is a method for driving a semiconductor optical integrated device comprising at least a first EA modulator section having an n-type first semiconductor layer, a first modulation layer, and a p-type first semiconductor layer and a second EA modulator section having an n-type second semiconductor layer, a second modulation layer, and a p-type second semiconductor layer, the first EA modulator section and the second EA modulator section being provided on a substrate along an optical waveguide direction, the n-type first semiconductor layer and the p-type second semiconductor layer being electrically connected, wherein an absolute value of a DC bias voltage Vp1 applied to the first EA modulator section is larger than an absolute value of a DC bias voltage Vp2 applied to the second EA modulator section.

A semiconductor optical integrated device according to the present disclosure includes: a substrate; a first EA modulator section formed on the substrate and comprising at least an n-type first semiconductor layer, a first modulation layer, and a p-type first semiconductor layer; and a second EA modulator section formed on the substrate and comprising at least an n-type second semiconductor layer, a second modulation layer having a width smaller than a width of the first modulation layer, and a p-type second semiconductor layer electrically connected to the n-type first semiconductor layer.

An optical module according to the present disclosure includes: a mounting substrate; a semiconductor optical integrated device mounted on the mounting substrate, the semiconductor optical integrated device including: a substrate; a first EA modulator section formed on the substrate and comprising at least an n-type first semiconductor layer, a first modulation layer, and a p-type first semiconductor layer; a second EA modulator section formed on the substrate and comprising at least an n-type second semiconductor layer, a second modulation layer, and a p-type second semiconductor layer electrically connected to the n-type first semiconductor layer; a wire bonding pad for a p-type electrode of a first EA modulator electrically connected to the p-type first semiconductor layer electrically connected to the p-type first semiconductor layer; and a wire bonding pad for an n-type electrode of a second EA modulator electrically connected to the n-type electrode of the second EA modulator electrically connected to the n-type second semiconductor layer; a first modulation signal line LN1 provided on the mounting substrate and electrically connected to the wire bonding pad for the p-type electrode of the first EA modulator through a wire; a second modulation signal line LN2 provided on the mounting substrate and electrically connected to the wire bonding pad for the n-type electrode of the second EA modulator through a wire; a first terminating resistor electrically connected to the wire bonding pad for the p-type electrode of the first EA modulator; and a second terminating resistor electrically connected to the wire bonding pad for the n-type electrode of the second EA modulator and having a resistance value different from the first terminating resistor.

A multi-level intensity modulation transceiver according to the present disclosure includes: a digital signal processing circuit for generating a multi-level intensity modulated digital signal on a basis of an input data signal; an analog-to-digital conversion circuit for converting the digital signal into an analog modulation signal; an amplifier circuit for amplifying the analog modulation signal; the above-mentioned semiconductor optical integrated device for inputting the amplified analog modulation signal; and an optical system for coupling a modulation signal emitted from the semiconductor optical integrated device to an optical fiber.

An optical line terminating device according to the present disclosure includes: a forward error correction circuit for correcting a data error on a basis of an input data signal; an amplifier circuit for amplifying an electric signal; the above-mentioned semiconductor optical integrated device for receiving the amplified electric signal; and an optical system for coupling a modulation signal emitted from the semiconductor optical integrated device to an optical fiber.

According to a method for driving a semiconductor optical integrated device of the present disclosure, the absolute value of the DC bias voltage applied to the first EA modulator section is set to be larger than the absolute value of the DC bias voltage applied to the second EA modulator section, thus providing an effect of improving the extinction ratio, wavelength chirp, and modulation bandwidth of the semiconductor optical integrated device.

According to the semiconductor optical integrated device of the present disclosure, the extinction ratio, wavelength chirp, and modulation bandwidth of the semiconductor optical integrated device are improved.

According to the optical module of the present disclosure, the modulation bandwidth difference between the first EA modulator section and the second EA modulator section is alleviated.

According to the multi-level intensity modulation transceiver of the present disclosure, the semiconductor optical integrated device of the present disclosure is used as a light source, thus providing an effect of obtaining a multi-level intensity modulation transceiver that is capable of broadband communication and has excellent performance in high-density mounting.

According to the optical line terminating device of the present disclosure, the semiconductor optical integrated device of the present disclosure is used as a light source, thus providing an effect of obtaining optical line terminating device that is capable of broadband communication and has low power consumption.

### BRIEF DESCRIPTION OF THE DRAWINGS

FIG. 1 is a cross-sectional view showing a device structure of an optical modulator integrated semiconductor laser which is an example of a semiconductor optical integrated device according to Embodiment 1;

FIG. 2 is a top view showing the device structure of the optical modulator integrated semiconductor laser which is an example of a semiconductor optical integrated device according to Embodiment 1;

FIG. 3 is a cross-sectional view explaining the operation of the optical modulator integrated semiconductor laser which is an example of a semiconductor optical integrated device according to Embodiment 1;

FIG. 4 is a schematic view showing the electric modulation waveform of the optical modulator integrated semiconductor laser which is an example of a semiconductor optical integrated device according to Embodiment 1;

FIG. 5 is a schematic view showing the electric modulation waveform of the optical modulator integrated semiconductor laser which is an example of a semiconductor optical integrated device according to Embodiment 1;

FIG. 6 is a cross-sectional view showing a device structure of an integrated optical modulator which is an example of a semiconductor optical integrated device according to Embodiment 2;

FIG. 7 is a top view showing a device structure of an optical modulator integrated semiconductor laser which is an example of a semiconductor optical integrated device according to Embodiment 3;

FIG. 8 is a cross-sectional view showing the device structure of the optical modulator integrated semiconductor laser which is an example of a semiconductor optical integrated device according to Embodiment 3;

FIG. 9 is a schematic view explaining the operation of the optical modulator integrated semiconductor laser which is an example of a semiconductor optical integrated device according to Embodiment 3;

FIG. 10 is a schematic view explaining the operation of the optical modulator integrated semiconductor laser which is an example of a semiconductor optical integrated device according to Embodiment 3;

FIG. 11 is a top view showing a device structure of an optical modulator integrated semiconductor laser which is an example of a semiconductor optical integrated device according to Embodiment 4;

FIG. 12 is a top view showing a structure of an optical module according to Embodiment 5;

FIG. 13 is a top view showing a structure of an optical module according to Embodiment 6;

FIG. 14 is a top view showing a structure of an optical module according to Embodiment 7;

FIG. 15 is a schematic diagram showing a configuration of a multi-level intensity modulation transceiver according to Embodiment 8;

FIG. 16 is a conceptual diagram showing the received waveform of the multi-level intensity modulation transceiver according to Embodiment 8;

FIG. 17 is a conceptual diagram showing the wavelength dependence of the optical absorption coefficient when a voltage is applied to an MQW layer of an optical modulator integrated semiconductor laser which is an example of a semiconductor optical integrated device;

FIG. 18 is a schematic diagram showing the configuration of an OLT in an optical line terminating device of a 50G-PON system according to Embodiment 9;

FIG. 19 is a schematic diagram showing the configuration of an ONU in the optical line terminating device of a 50G-PON system according to Embodiment 9.

### DETAILED DESCRIPTION OF THE PREFERRED EMBODIMENTS OF THE DISCLOSURE

### Embodiment 1

### Device Structure of Semiconductor Optical Integrated Device According to Embodiment 1

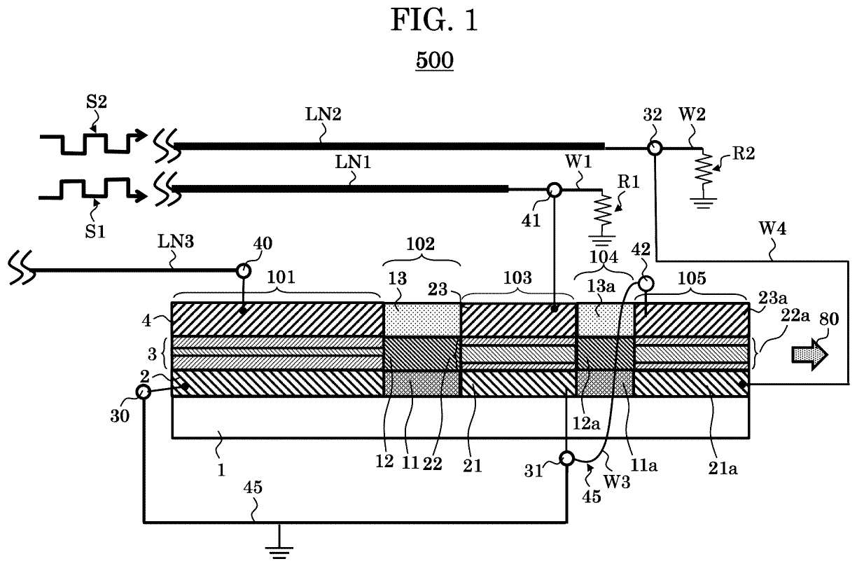

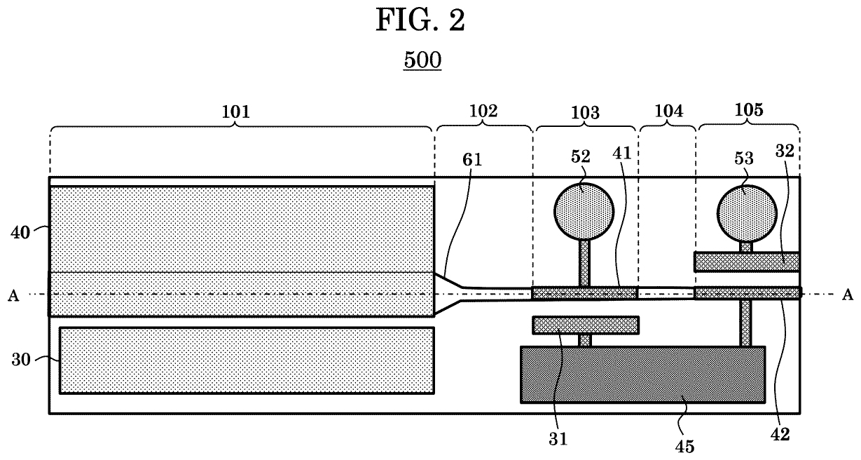

FIG. 1 and FIG. 2 are a cross-sectional view and a top view, respectively, showing the device structure of a semiconductor optical integrated device 500 according to Embodiment 1. FIG. 1 also shows the state of the wiring to the semiconductor optical integrated device 500.

As shown in FIG. 1, the semiconductor optical integrated device 500 according to Embodiment 1 comprises a semiconductor laser section 101 comprising a DFB (Distributed FeedBack) laser, a first connecting waveguide section 102, a first EA modulator section 103, a second connecting waveguide section 104, and a second EA modulator section 105, which are connected sequentially along the optical waveguide direction on a semi-insulating substrate 1. The section from the semiconductor laser section 101 to the second EA modulator section 105 is collectively referred to as the optical waveguide section.

The semiconductor laser section 101 comprising the DFB laser includes: an n-type cladding layer 2 having a carrier concentration of 5×10¹⁷ to 8×10¹⁸ cm⁻³ and a thickness of 0.1 to 5.0 μm; an active layer 3; and a p-type cladding layer 4 having a carrier concentration of 5×10¹⁷ to 8×10¹⁸ cm⁻³ and a thickness of 0.1 to 5.0 μm; which are sequentially formed above a semi-insulating substrate 1 such as an Fe-doped InP substrate, a p-type electrode 40 of the semiconductor laser section electrically connected to the p-type cladding layer 4 of the semiconductor laser section 101; and an n-type electrode 30 of the semiconductor laser section electrically connected to the n-type cladding layer 2 of the semiconductor laser section 101. Note that the n-type cladding layer 2 and the p-type cladding layer 4 may be referred to as an n-type semiconductor layer and a p-type semiconductor layer, respectively.

The active layer 3 includes a diffraction grating layer, a multiple quantum well layer (MQW layer), and optical confinement layers formed on the upper and lower surfaces of the multiple quantum well layer (MQW layer), respectively (both not shown). The total thickness of the active layer 3 is 100 to 500 nm.

The first connecting waveguide section 102, in which a waveguide is connected to the semiconductor laser section 101, includes: an i-type first lower cladding layer 11 having a carrier concentration of 5×10¹⁷ cm⁻³ or less and a thickness of 0.1 to 5.0 μm; an i-type first waveguide layer 12 having a carrier concentration of 5×10¹⁷ cm⁻³ or less and a thickness of 50 to 500 nm and a refractive index higher than that of the cladding layer; and an i-type first upper cladding layer 13 having a carrier concentration of 5×10¹⁷ cm⁻³ or less and a thickness of 0.1 to 5.0 μm, which are sequentially formed above the semi-insulating substrate 1.

The i-type first lower cladding layer 11, the i-type first waveguide layer 12, and the i-type first upper cladding layer 13 of the first connecting waveguide section 102 may be p-type or n-type with a carrier concentration of 5×10¹⁸ cm⁻³ or less, because an isolation resistance between the semiconductor laser section 101 and the first EA modulator section 103 is high in the case where the waveguide width is 2 μm or less. Setting the isolation resistance between the semiconductor laser section 101 and the first EA modulator section 103 to 500 Ω or more, which is ten times or more higher than the impedance of 50 Ω during EA modulator drive, can prevent high-frequency leakage from the first EA modulator section 103 to the semiconductor laser section 101.

The first EA modulator section 103, which is connected to the first connecting waveguide section 102, includes: an n-type first semiconductor layer 21 having a carrier concentration of 5×10¹⁷ to 8×10¹⁸ cm⁻³ and a thickness of 0.1 to 5.0 μm; a first modulation layer 22; a p-type first semiconductor layer 23 having a carrier concentration of 5×10¹⁷ to 8×10¹⁸ cm⁻³ and a thickness of 0.1 to 5.0 μm; which are sequentially formed above the semi-insulating substrate 1, a p-type electrode 41 of the first EA modulator electrically connected to the p-type first semiconductor layer 23 of the first EA modulator section 103; and an n-type electrode 31 of the first EA modulator electrically connected to the n-type first semiconductor layer 21.

The first modulation layer 22 of the first EA modulator section 103 comprises an i-type multiple quantum well layer (MQW layer) having a carrier concentration of 5×10¹⁷ cm⁻³ or less and optical confinement layers formed above and below the multiple quantum well layer (MQW layer), respectively (both not shown). The total thickness of the first modulation layer 22 is 50 to 500 nm.

The second connecting waveguide section 104, in which a waveguide is connected to the first EA modulator section 103, includes: an i-type second lower cladding layer 11a having a carrier concentration of 5×10¹⁷ cm⁻³ or less and a thickness of 0.1 to 5.0 μm; an i-type second waveguide layer 12a having a carrier concentration of 5×10¹⁷ cm⁻³ or less and a thickness of 50 to 500 nm and a refractive index higher than that of the cladding layer; and an i-type second upper cladding layer 13a having a carrier concentration of 5×10¹⁷ cm⁻³ or less and a thickness of 0.1 to 5.0 μm, which are sequentially formed above the semi-insulating substrate 1.

Note that the second connecting waveguide section 104 may sometimes be referred to simply as the connecting waveguide section. Additionally, the i-type second lower cladding layer 11a, the second waveguide layer 12a, and the i-type second upper cladding layer 13a may sometimes be referred to simply as the lower cladding layer, the waveguide layer, and the upper cladding layer, respectively.

The i-type second lower cladding layer 11a, the i-type second waveguide layer 12a, and the i-type second upper cladding layer 13a may be p-type or n-type with a carrier concentration of 5×10¹⁸ cm⁻³ or less, because the isolation resistance between the first EA modulator section 103 and the second EA modulator section 105 becomes high in the case where the waveguide width is 2 μm or less. Setting the isolation resistance between the first EA modulator section 103 and the second EA modulator section 105 to 500 Ω or more, which is ten times or more higher than the impedance of 50 Ω during EA modulator drive, can prevent high-frequency leakage from the second EA modulator section 105 to the first EA modulator section 103.

The second EA modulator section 105 connected to the second connecting waveguide section 104 includes: an n-type second semiconductor layer 21a having a carrier concentration of 5×10¹⁷ to 8×10¹⁸ cm⁻³ and a thickness of 0.1 to 5.0 μm; a second modulation layer 22a, a p-type second semiconductor layer 23a having a carrier concentration of 5×10¹⁷ to 8×10¹⁸ cm⁻³ and a thickness of 0.1 to 5.0 μm; which are sequentially formed above the semi-insulating substrate 1, a p-type electrode 42 of the second EA modulator electrically connected to the p-type second semiconductor layer 23a of the second EA modulator section 105; and an n-type electrode 32 of the second EA modulator electrically connected to the n-type second semiconductor layer 21a.

The second modulation layer 22a of the second EA modulator section 105 comprises an i-type multiple quantum well layer (MQW layer) having a carrier concentration of 5×10¹⁷ cm⁻³ or less, and optical confinement layers formed above and below the multiple quantum well layer (MQW layer), respectively (both not shown). The total thickness of the second modulation layer 22a is 50 to 500 nm.

The n-type electrode 31 of the first EA modulator of the first EA modulator section 103 and the p-type electrode 42 of the second EA modulator of the second EA modulator section 105 are electrically connected by an electrode or wire wiring. In the present disclosure, an electrode pattern or wire wiring that electrically connects the n-type electrode 31 of the first EA modulator and the p-type electrode 42 of the second EA modulator is referred to as a common electrode 45. In the example shown in FIG. 1, the common electrode 45 is electrically connected to the ground and the n-type electrode 30 of the semiconductor laser section 101. However, the common electrode 45 is not necessarily connected to either or both of the ground and the n-type electrode 30 of the semiconductor laser section.

The first modulation signal line LN1 for transmitting the first modulation signal S1 for modulating the first EA modulator section 103 is electrically connected to the p-type electrode 41 of the first EA modulator of the first EA modulator section 103. The second modulation signal line LN2 for transmitting the second modulation signal S2 for modulating the second EA modulator section 105 is electrically connected to the n-type electrode 32 of the second EA modulator of the second EA modulator section 105. Since the first modulation signal line LN1 and the second modulation signal line LN2 are arranged close to each other in parallel, electromagnetic fields are coupled to each other.

The first modulation signal line LN1 and the second modulation signal line LN2 are electrically connected to drivers (not shown) that output a modulation signal, respectively. The first modulation signal S1 and the second modulation signal S2, which transmit the first modulation signal line LN1 and the second modulation signal line LN2, respectively, are modulated as signals of opposite phases, such as a positive-phase signal and a negative-phase signal. A DC current is supplied to the semiconductor laser section 101 through the semiconductor laser section current line LN3.

Next, the configuration of the upper surface side of the optical modulator integrated semiconductor laser 500 will be described with reference to the top view shown in FIG. 2. The semiconductor laser section 101 has the n-type electrode 30 of the semiconductor laser section formed on the n-type cladding layer 2 and electrically connected to the n-type cladding layer 2, and the p-type electrode 40 of the semiconductor laser section formed on the p-type cladding layer 4 and electrically connected to the p-type cladding layer 4.

In the first connecting waveguide section 102, the waveguide width changes in a tapered manner from the buried waveguide on the semiconductor laser section 101 side to the high-mesa waveguide on the first EA modulator section 103 side. That is, the first connecting waveguide section 102 has a waveguide conversion section 61 for converting the buried waveguide to the high-mesa waveguide.

The first EA modulator section 103 has the n-type electrode 31 of the first EA modulator formed on the n-type first semiconductor layer 21 and electrically connected to the n-type first semiconductor layer 21, and the p-type electrode 41 of the first EA modulator formed on the p-type first semiconductor layer 23 and electrically connected to the p-type first semiconductor layer 23. The p-type electrode 41 of the first EA modulator is electrically connected to a wire bonding pad 52 for the p-type electrode of the first EA modulator provided on the surface of the optical modulator integrated semiconductor laser 700 through an electrode pattern or wire wiring.

The second EA modulator section 105 has the n-type electrode 32 of the second EA modulator formed on the n-type second semiconductor layer 21a and electrically connected to the n-type second semiconductor layer 21a, and the p-type electrode 42 of the second EA modulator formed on the p-type second semiconductor layer 23a and electrically connected to the p-type second semiconductor layer 23a. The n-type electrode 32 of the second EA modulator is electrically connected to a wire bonding pad 53 for the n-type electrode of the second EA modulator provided on the surface of the optical modulator integrated semiconductor laser 700 through an electrode pattern or wire wiring.

The common electrode 45 is provided on the surface of the optical modulator integrated semiconductor laser 700. The common electrode 45 is electrically connected to the n-type electrode 31 of the first EA modulator and the p-type electrode 42 of the second EA modulator through an electrode pattern or wire wiring. In Embodiment 1, the common electrode 45 itself is also formed by an electrode pattern or wire wiring.

### Action of Optical Modulator Integrated Semiconductor Laser According to Embodiment 1

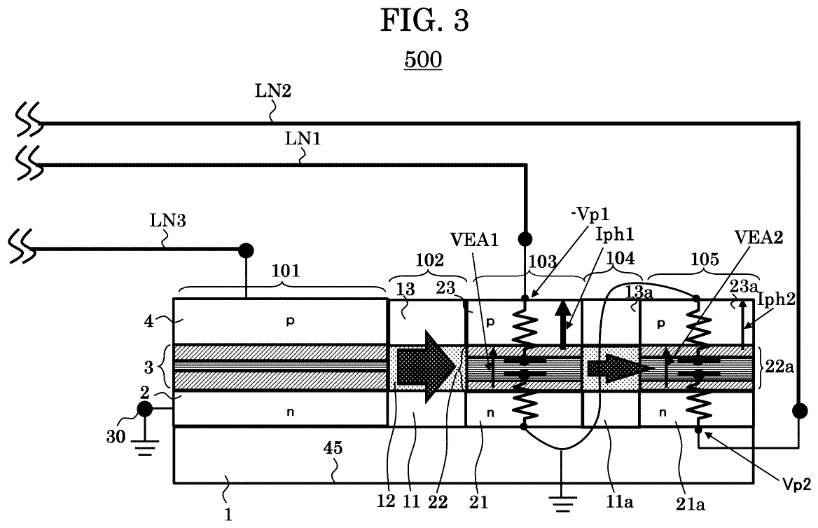

The action of the optical modulator integrated semiconductor laser 500 according to Embodiment 1 will be described below with reference to FIG. 3. DC current is injected from the semiconductor laser section current line LN3 into the semiconductor laser section 101, thus the DFB laser constituting the semiconductor laser section 101 emits light. The light emitted from the semiconductor laser section 101 passes through the first connecting waveguide section 102 and reaches the first EA modulator section 103.

The first modulation signal S1, that is, the modulated voltage signal, is input from the first modulation signal line LN1 to the p-type first semiconductor layer 23 of the first EA modulator section 103, and modulates the light intensity at the extinction ratio Ex1 (dB). The light modulated by the first EA modulator section 103 passes through the second connecting waveguide section 104 and then enters the second EA modulator section 105. The second modulation signal S2, that is, the modulated voltage signal, is input from the second modulation signal line LN2 to the n-type second semiconductor layer 21a of the second EA modulator section 105, and modulates the light intensity at the extinction ratio Ex2 (dB), and emits the modulated light 80 from the end surface to the outside.

The positive-phase signal and the negative-phase signal, that are, the first modulation signal S1 and the second modulation signal S2, are input to the first modulation signal line LN1 and the second modulation signal line LN2, respectively. Consequently, the first EA modulator section 103 and the second EA modulator section 105 appear to be differentially driven. However, the optical modulator integrated semiconductor laser 500 according to Embodiment 1 is characterized in that the first EA modulator section 103 and the second EA modulator section 105 operate as single-phase EA modulators, respectively.

Consider the case where DC bias voltage −Vp1 is applied to the first EA modulator section 103 and DC bias voltage Vp2 (Vp1=Vp2) is applied to the second EA modulator section 105, as shown in FIG. 3. Assuming that the photocurrent flowing through the first EA modulator section 103 at the time of light input is Iph1, the resistance of the n-type first semiconductor layer 21 of the first EA modulator section 103 is Rn1, and the resistance of the p-type first semiconductor layer 23 of the first EA modulator section 103 is Rp1, the voltage amplitude VEA1 applied to the first modulation layer 22 of the first EA modulator section 103 at the time of light input from the semiconductor laser section 101 is expressed by the following Expression (1). Expression (1) means that the potential of the voltage amplitude VEA1 shifts to the positive side as the photocurrent Iph1 becomes larger.

$$VEA 1 = - Vp 1 + Iph 1 \times ( Rp 1 + Rn 1 ) \qquad ( 1 )$$

Assuming that the photocurrent flowing through the second EA modulator section 105 at the time of light input is Iph2, the resistance of the n-type second semiconductor layer 21a of the second EA modulator section 105 is Rn2, and the resistance of the p-type second semiconductor layer 23a of the second EA modulator section 105 is Rp2, the voltage amplitude VEA2 applied to the second modulator layer 22a of the second EA modulator section 105 is expressed by the following Expression (2). Expression (2) means that the potential of the voltage amplitude VEA2 shifts to the positive side as the photocurrent Iph2 becomes larger.

$$VEA 2 = - Vp 2 + Iph 2 \times ( Rp 2 + Rn 2 ) \qquad ( 2 )$$

Consider the case where the DC bias voltage is Vp1=Vp2 and the lengths of the first EA modulator section 103 and the second EA modulator section 105 along the optical waveguide direction are the same.

Normally, the p-type first semiconductor layer 23 has a higher resistance than the n-type first semiconductor layer 21, and the p-type second semiconductor layer 23a has a higher resistance than the n-type second semiconductor layer 21a. That is, the following relationship in Expression (3) is satisfied.

$$Rp 1 = Rp 2 > Rn 1 = Rn 2 \qquad ( 3 )$$

Among the two EA modulator sections, the light intensity of the first EA modulator section 103 on the light incident side is larger and the light absorption amount thereof is also larger than that of the second EA modulator section 105. The photocurrent Iph1 flowing through the first EA modulator section 103 when the light is incident and the photocurrent Iph2 flowing through the second EA modulator section 105 when the light is incident satisfy the following Expression (4).

$$Iph 1 > Iph 2 \qquad ( 4 )$$

When the relationship in Expression (4) is satisfied, the entire voltage amplitude VEA1 applied to the first modulation layer 22 of the first EA modulator section 103 is shifted to the positive side than the entire voltage amplitude VEA2 applied to the second modulation layer 22a of the second EA modulator section 105. That is, the following relationship in Expression (5) is satisfied.

$$VEA 1 > VEA 2 \qquad ( 5 )$$

As a result of the relationship in Expression (5) being satisfied, the extinction ratio of the first EA modulator section 103 becomes smaller than that of the second EA modulator section 105, resulting in problems such as a larger wavelength chirp and a narrower modulation bandwidth.

When light is turned off during modulation, the photocurrent increases more. Since the first EA modulator section 103 is located closer to the semiconductor laser section 101 than the second EA modulator section 105, the light intensity incident on the first EA modulator section 103 is larger. As a result, the voltage amplitude VEA1 applied to the first modulation layer 22 of the first EA modulator section 103 becomes smaller than the voltage amplitude VEA2 applied to the second modulation layer 22a of the second EA modulator section 105, which causes a problem.

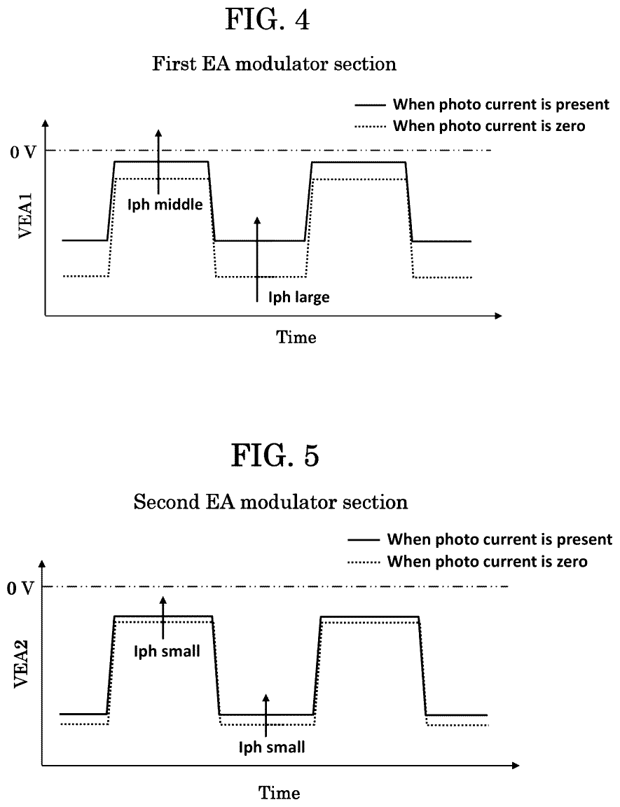

The above-mentioned problems will be described with reference to FIGS. 4 and 5. FIG. 4 is a schematic diagram for explaining the relationship between the voltage amplitude VEA1 applied to the first modulation layer 22 of the first EA modulator section 103 and the photocurrent Iph1. In FIG. 4, the vertical axis represents the voltage amplitude VEA1, and the horizontal axis represents time. The negative value of the voltage amplitude VEA1 means that the potential on the upper side (p-type layer side) of the arrow indicating the voltage amplitude VEA1 in FIG. 3 is lower than the potential on the lower side (n-type layer side).

FIG. 5 is a schematic diagram for explaining the relationship between the voltage amplitude VEA2 applied to the second modulation layer 22a of the second EA modulator section 105 and the photocurrent Iph2. In FIG. 5, the vertical axis represents the voltage amplitude VEA2, and the horizontal axis represents time. The negative value of the voltage amplitude VEA2 means that the potential on the upper side (p-type layer side) of the arrow indicating the voltage amplitude VEA2 in FIG. 3 is lower than the potential on the lower side (n-type layer side).

As can be seen from FIG. 5, since the photocurrent Iph2 flowing through the second EA modulator section 105 is smaller than the photocurrent Iph1 flowing through the first EA modulator section 103, the voltage amplitude VEA1 is smaller than the voltage amplitude VEA2.

As can be seen from FIGS. 4 and 5, since the photocurrent Iph1 flowing through the first EA modulator section 103 is larger than the photocurrent Iph2 flowing through the second EA modulator section 105, the voltage amplitude VEA1 becomes smaller than the voltage amplitude VEA2. That is, it can be seen that the voltage amplitude of the first EA modulator section 103 is smaller than that of the second EA modulator section 105.

As a measure against the above-mentioned problem, in the method for driving the optical modulator integrated semiconductor laser 500 according to Embodiment 1, the DC bias voltage (−Vp1) applied to the first EA modulator section 103 and the DC bias voltage Vp2 applied to the second EA modulator section 105 are set so as to satisfy the following Expression (6).

$$\vert Vp 2 \vert < \vert Vp 1 \vert \qquad ( 6 )$$

That is, by making the absolute value |Vp1| of the DC bias voltage (−Vp1) larger than the absolute value |Vp2| of the DC bias voltage Vp2, the entire voltage amplitude VEA1 applied to the first modulation layer 22 of the first EA modulator section 103 is shifted to the negative side, thereby reducing both the difference of the voltage amplitude VEA2 applied to the second modulation layer 22a of the second EA modulator section 105. As a result, problems such as extinction ratio, wavelength chirp, and modulation bandwidth of the optical modulator integrated semiconductor laser 500 are alleviated.

The absolute value |Vp1| of the DC bias voltage (−Vp1) applied to the first EA modulator section 103 is preferably smaller than three times the absolute value |Vp2| of the DC bias voltage Vp2 applied to the second EA modulator section 105, that is, smaller than 3×|Vp2|. That is, it is preferable that the following Expression (7) is satisfied.

$$\vert Vp 2 \vert < \vert Vp 1 \vert < 3 \times \vert Vp 2 \vert \qquad ( 7 )$$

### Effects of Embodiment 1

In the method for driving the semiconductor optical integrated device according to Embodiment 1, the absolute value of the DC bias voltage applied to the first EA modulator section is set to be larger than the absolute value of the DC bias voltage applied to the second EA modulator section, thus providing an effect of improving the extinction ratio, wavelength chirp, and modulation bandwidth of the semiconductor optical integrated device.

Contrary to the present embodiment, the same effect can be also achieved when the p-type electrode 41 of the first EA modulator in the first EA modulator section 103 and the n-type electrode 32 of the second EA modulator in the second EA modulator section 105 are electrically connected by wire wiring or the like, and the first modulation signal line LN1 is connected to the n-type electrode 31 of the first EA modulator in the first EA modulator section 103, and the second modulation signal line LN2 is connected to the p-type electrode 42 of the second EA modulator in the second EA modulator section 105.

### Embodiment 2

### Device Structure of Semiconductor Optical Integrated Device According to Embodiment 2

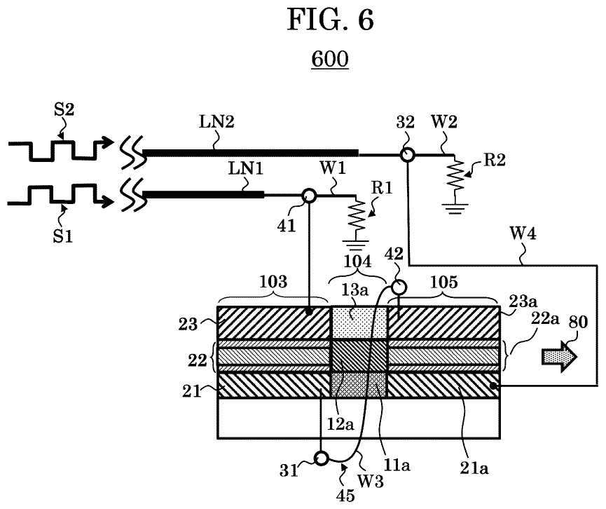

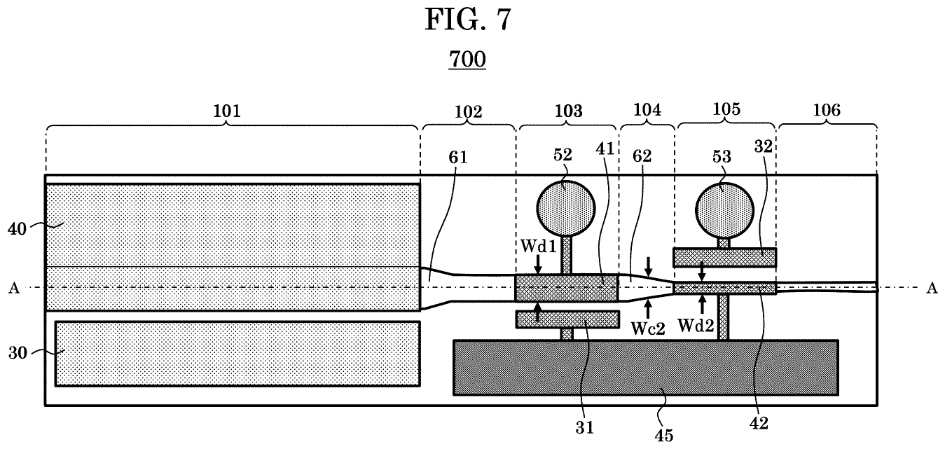

FIG. 6 is a cross-sectional view of a device structure of an integrated optical modulator 600 which is an example of a semiconductor optical integrated device according to Embodiment 2.

The integrated optical modulator 600 is composed of a portion of an optical modulator integrated semiconductor laser 500 that is an example of a semiconductor optical integrated device according to Embodiment 1, in which the semiconductor laser section 101 and the first connecting waveguide section 102 are removed. The integrated optical modulator 600 is an example of a semiconductor optical integrated device.

That is, the integrated optical modulator 600 comprises: a first EA modulator section 103; a second connected waveguide portion 104; and a second EA modulator section 105, which are sequentially connected along the optical waveguide direction on a semi-insulating substrate 1.

### Method for Driving Semiconductor Optical Integrated Device According to Embodiment 2

The method for driving the integrated optical modulator 600 is the same as the method for driving a semiconductor optical integrated device according to Embodiment 1 except that laser light enters from a semiconductor laser placed outside the integrated optical modulator 600, thus a detailed description thereof will be omitted.

### Effects of Embodiment 2

In the above method for driving a semiconductor optical integrated device according to Embodiment 2, the absolute value of the DC bias voltage applied to the first EA modulator section is set larger than the absolute value of the DC bias voltage applied to the second EA modulator section, thus providing an effect of improving the extinction ratio, wavelength chirp, and modulation bandwidth of the semiconductor optical integrated device.

### Embodiment 3

### Device Structure of Semiconductor Optical Integrated Device According to Embodiment 3

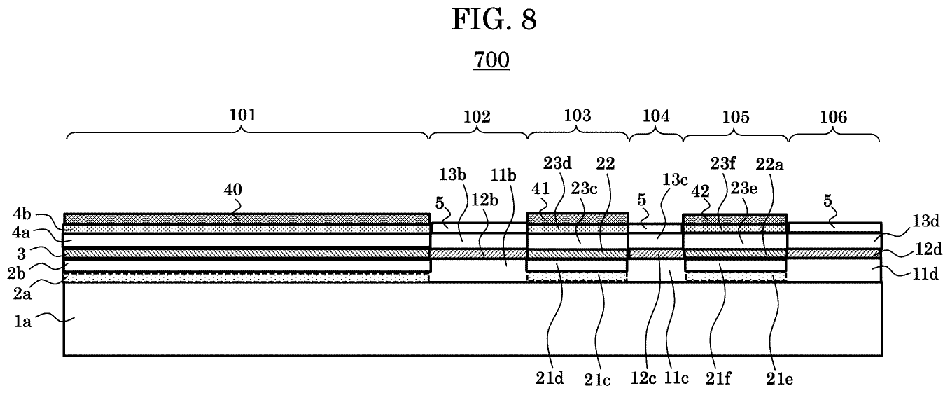

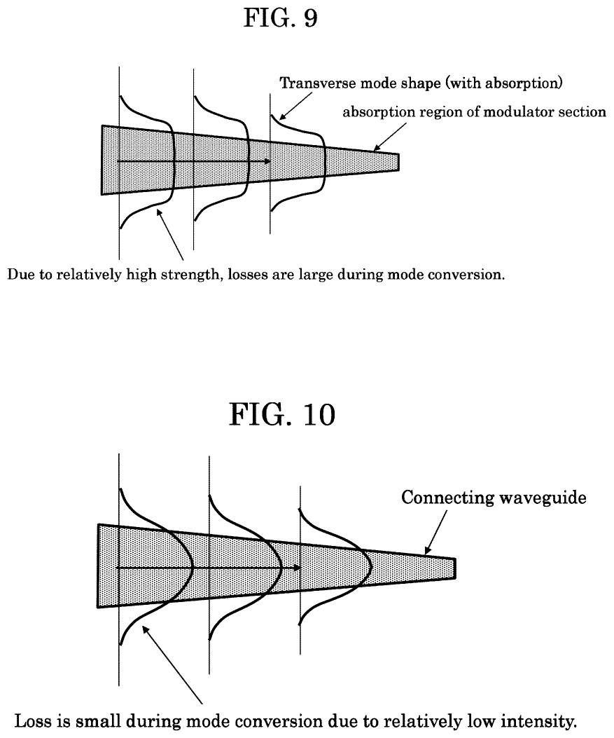

FIG. 7 is a top view of a device structure of an optical modulator integrated semiconductor laser 700 which is an example of a semiconductor optical integrated device according to Embodiment 3. FIG. 8 is a cross-sectional view of the device structure of the optical modulator integrated semiconductor laser 700 which is an example of a semiconductor optical integrated device according to Embodiment 3. FIGS. 9 and 10 are schematic views explaining the operation of the optical modulator integrated semiconductor laser 700 which is an example of a semiconductor optical integrated device according to Embodiment 3. FIG. 8 is a cross-sectional view taken along line A-A in the top view shown in FIG. 7.

As shown in the top view of FIG. 7, the optical modulator integrated semiconductor laser 700, which is an example of a semiconductor optical integrated device according to Embodiment 3, comprises: a semiconductor laser section 101 composed of a DFB laser; a first connecting waveguide section 102, a first EA modulator section 103; a second connecting waveguide section 104; a second EA modulator section 105; and a waveguide lens section 106, which are sequentially connected along the optical waveguide direction on an Fe-doped InP substrate 1a. Note that, it is also possible to remove the semiconductor laser section 101 and the waveguide lens section 106 from the integrated optical modulator semiconductor laser 700 to form an integrated optical modulator configuration.

The semiconductor laser section 101 comprising the DFB laser shown in the cross-sectional view of FIG. 8 includes: an n-type InGaAsP conductive layer 2a having a carrier concentration of 5×10¹⁷ to 8×10¹⁸ cm⁻³ and a thickness of 0.1 to 1.0 μm; an n-type InP cladding layer 2b having a carrier concentration of 5×10¹⁷ to 8×10¹⁸ cm⁻³ and a thickness of 0.1 to 3.0 μm; an active layer 3; a p-type InP cladding layer 4a having a carrier concentration of 5×10¹⁷ to 8×10¹⁸ cm⁻³ and a thickness of 0.1 to 3.0 μm; a p-type InGaAs contact layer 4b having a carrier concentration of 5×10¹⁷ to 8×10¹⁸ cm⁻³ and a thickness of 0.1 to 1.0 μm; which are sequentially formed above the Fe-doped InP substrate 1a, and a p-type electrode 40 of the semiconductor laser section using a metal material such as Ti, Pt, and Au.

The active layer 3 has a multi-layer structure with a total thickness of 80 to 400 nm. The active layer 3 comprises: a diffraction grating layer made of InGaAsP or InAlGaAs; an InP barrier layer; optical confinement layers made of InGaAsP or InAlGaAs; and a multiple quantum well layer (MQW layer) made of InGaAsP or InAlGaAs. The width of the active layer 3 is 1 to 2 μm. The active layer 3 has a buried waveguide structure in which both sides of the active layer 3 are buried with a current blocking layer 6 made of InP.

The outside of the buried waveguide is etched until the surface of the n-type InGaAsP conductive layer 2a is reached, and then the n-type electrode 30 of the semiconductor laser section is formed on the n-type InGaAsP conductive layer 2a. Both side surfaces of the buried waveguide are covered with an insulating protection film 5. The length of the semiconductor laser section 101 along the optical waveguide direction is 150 to 1000 μm.

The diffraction grating (not shown) of the DFB laser constituting the semiconductor laser section 101 may have a λ/4 shift structure. An anti-reflection film (not shown) is formed on the rear-end surface of the DFB laser. But in the case of an asymmetric structure in which the λ/4 shift structure is not located at the center, a high-reflection film of 70% or more may be formed on the rear-end surface side.

As shown in the cross-sectional view of FIG. 8, the first connecting waveguide section 102, in which a waveguide is connected to the semiconductor laser section 101 comprising the DFB laser, includes: a first lower cladding layer 11b made of i-type, n-type or p-type InP and having a carrier concentration of 2×10¹⁸ cm⁻³ or less and a thickness of 0.1 to 3.0 μm; a first waveguide layer 12b made of i-type, n-type or p-type InGaAsP and having a carrier concentration of 1×10¹⁸ cm⁻³ or less and a thickness of 80 to 400 nm; and a first upper cladding layer 13b made of i-type, n-type or p-type InP and having a carrier concentration of 2×10¹⁸ cm⁻³ or less and a thickness of 0.1 to 3.0 μm, which are sequentially formed above the Fe-doped InP substrate 1a. The first waveguide layer 12b made of InGaAsP may be composed of an InAlGaAs waveguide layer.

The first connecting waveguide section 102 has a length of 40 to 350 μm along the optical waveguide direction. The waveguide width of the first connecting waveguide section 102 is tapered from the buried waveguide on the semiconductor laser section 101 side to the high-mesa waveguide on the first EA modulator section 103 side, and thus the waveguide is converted from the buried waveguide to the high-mesa waveguide. The width of the high-mesa waveguide is 0.5 to 2 μm.

As shown in the cross-sectional view of FIG. 8, the first EA modulator section 103, in which a waveguide is connected to the first connecting waveguide section 102, includes: an n-type InGaAsP first conductive layer 21c having a carrier concentration of 5×10¹⁷ to 8×10¹⁸ cm⁻³ and a thickness of 0.1 to 1.0 μm; an n-type InP first cladding layer 21d having a carrier concentration of 5×10¹⁷ to 8×10¹⁸ cm⁻³ and a thickness of 0.1 to 3.0 μm; a first modulation layer 22; a p-type InP first cladding layer 23c having a carrier concentration of 5×10¹⁷ to 8×10¹⁸ cm⁻³ and a thickness of 0.1 to 3.0 μm; a p-type InGaAs first contact layer 23d having a carrier concentration of 5×10¹⁷ to 8×10¹⁸ cm⁻³ and a thickness of 0.1 to 1.0 μm; which are sequentially formed above the Fe-doped InP substrate 1a, and an p-type electrode 41 of the first EA modulator using a metallic material such as Ti, Pt, and Au.

The first modulation layer 22 comprises a multi-layer structure composed of InGaAsP or InAlGaAs optical confinement layers and an InGaAsP or InAlGaAs multiple quantum well layer with a thickness of 80 to 400 nm. The width of the first modulation layer 22 is 0.5 to 2 μm.

The n-type InGaAsP first conductive layer 21c and the n-type InP first cladding layer 21d are collectively referred to as an n-type first semiconductor layer. The p-type InP first cladding layer 23c and the p-type InGaAs first contact layer 23d are collectively referred to as a p-type first semiconductor layer.

The outside of the high-mesa waveguide is etched up to the Fe-doped InP substrate 1a. But the n-type InGaAsP first conductive layer 21c remains on at least one side, and the n-type electrode 31 of the first EA modulator is formed on the n-type InGaAsP first conductive layer 21c in the remaining area thereof. The width of the n-type InGaAsP first conductive layer 21c remaining on the outside of the high-mesa waveguide is 1 to 30 μm. The length of the first EA modulator section 103 along the optical waveguide direction is 30 to 200 μm.

The second connecting waveguide section 104, in which a waveguide is connected to the first EA modulator section 103, includes: a second lower cladding layer 11c made of i-type, n-type or p-type InP and having a carrier concentration of 2×10¹⁸ cm⁻³ or less and a thickness of 0.1 to 3.0 μm; a second waveguide layer 12c made of i-type, n-type or p-type InGaAsP and having a carrier concentration of 1×10¹⁸ cm⁻³ or less and a thickness of 80 to 400 nm; and a second upper cladding layer 13c made of i-type, n-type or p-type InP and having a carrier concentration of 2×10^{18 cm -3} or less and a thickness of 0.1 to 3.0 μm, which are sequentially formed above the Fe-doped InP substrate 1a. The second waveguide layer 12c made of InGaAsP may be made of InAlGaAs.

The second connecting waveguide section 104 comprises the high-mesa waveguide having a length of 40 to 350 μm along the optical waveguide direction. The width of the high-mesa waveguide is 0.5 to 2 μm. The waveguide structure of the second connecting waveguide section 104 is similar to that of the first connecting waveguide section 102.

That is, the second connecting waveguide section 104 comprises the second lower cladding layer 11c made of i-type, n-type, or p-type InP, the second waveguide layer 12c made of i-type, n-type, or p-type InGaAsP, and the second upper cladding layer 13c made of i-type, n-type, or p-type InP, which are sequentially formed above the Fe-doped InP substrate 1a.

The second EA modulator section 105, in which a waveguide is connected to the second connecting waveguide section 104, includes: an n-type InGaAsP second conductive layer 21e having a carrier concentration of 5×10¹⁷ to 8×10¹⁸ cm⁻³ and a thickness of 0.1 to 1.0 μm; an n-type InP second cladding layer 21f having a carrier concentration of 5×10¹⁷ to 8×10¹⁸ cm⁻³ and a thickness of 0.1 to 3.0 μm; a second modulation layer 22a; a p-type InP second cladding layer 23e having a carrier concentration of 5×10¹⁷ to 8×10¹⁸ cm⁻³ and a thickness of 0.1 to 3.0 μm; a p-type InGaAs second contact layer 23f having a carrier concentration of 5×10¹⁷ to 8×10¹⁸ cm⁻³ and a thickness of 0.1 to 1.0 μm, which are sequentially formed above the Fe-doped InP substrate 1a, and an p-type electrode 42 of the second EA modulator using a metallic material such as Ti, Pt, and Au.

The n-type InGaAsP second conductive layer 21e and the n-type InP second cladding layer 21f are collectively referred to as an n-type second semiconductor layer. The p-type InP second cladding layer 23e and the p-type InGaAs second contact layer 23f are collectively referred to as a p-type second semiconductor layer.

The second modulation layer 22a comprises a multilayer structure consisting InGaAsP or InAlGaAs optical confinement layers and an InGaAsP or InAlGaAs multiple quantum well layer with a thickness of 80 to 400 nm. The width of the second modulation layer 22 is 0.5 to 2 μm.

The outside of the high-mesa waveguide is etched up to the Fe-doped InP substrate 1a. But the n-type InGaAsP second conductive layer 21e remains on at least one side, and the n-type electrode 32 of the second EA modulator is formed on the n-type InGaAsP second conductive layer 21e. The width of the n-type InGaAsP second conductive layer 21e remaining on the outside of the high-mesa waveguide is 1 to 30 μm. The length of the second EA modulator section 105 along the optical waveguide direction is 30 to 200 μm.

The waveguide lens section 106, in which a waveguide is connected to the second EA modulator section 105, includes: an n-type or a p-type InP third lower cladding layer 11d having a carrier concentration of 2×10¹⁸ cm⁻³ or less and a thickness of 0.1 to 3.0 μm; an n-type or a p-type InGaAsP third waveguide layer 12d having a carrier concentration of 1×10¹⁸ cm⁻³ or less and a thickness of 80 to 400 nm; and an n-type or a p-type InP third upper cladding layer 13d having a carrier concentration of 2×10¹⁸ cm⁻³ or less and a thickness of 0.1 to 3.0 μm, which are sequentially formed above the Fe-doped InP substrate. The InGaAsP third waveguide layer 12d may be composed of an InAlGaAs waveguide layer. The width of the high-mesa waveguide gradually widens toward the front-end surface, and thus the waveguide is converted from the high-mesa waveguide to the buried waveguide. The modulated light 80 is emitted from the front-end surface. A non-reflection film (not shown) is formed on the front-end surface.

The semiconductor layers described above are crystal-grown by MOCVD (Metal Organic Chemical Vapor Deposition) or MBE (Molecular Beam Epitaxy). Simultaneous crystal growth of each modulation layer of the first EA modulator section 103 and the second EA modulator section 105 improves the effect of canceling out electromagnetic interference by aligning the optical absorption characteristics. In addition, simultaneous crystal growth of each InGaAsP waveguide layer of the first connecting waveguide section 102 and the second connecting waveguide section 104 also improves the effect of canceling out electromagnetic interference by aligning the modes of light propagation.

Next, the configuration of the upper surface side of the optical modulator integrated semiconductor laser 700 will be described with reference to the top view of FIG. 7. The semiconductor laser section 101 includes: the n-type electrode 30 of the semiconductor laser section formed on the n-type InGaAsP conductive layer 2a and electrically connected to the n-type InGaAsP conductive layer 2a; and the p-type electrode 40 of the semiconductor laser section formed on the p-type InGaAs contact layer 4b and electrically connected to the p-type InGaAs contact layer 4b.

In the first connecting waveguide section 102, the waveguide width changes in a tapered manner from the buried waveguide on the semiconductor laser section 101 side to the high-mesa waveguide on the first EA modulator section 103 side. That is, the first connecting waveguide section 102 has a waveguide conversion section 61 for converting from the buried waveguide to the high-mesa waveguide.

The first EA modulator section 103 includes: the n-type electrode 31 of the first EA modulator formed on the n-type InGaAsP first conductive layer 21c and electrically connected to the n-type InGaAsP first conductive layer 21c; and the p-type electrode 41 of the first EA modulator formed on the p-type InGaAs first contact layer 23d and electrically connected to the p-type InGaAs first contact layer 23d. The p-type electrode 41 of the first EA modulator is electrically connected to a wire bonding pad 52 for the p-type electrode of the first EA modulator formed on the surface of the optical modulator integrated semiconductor laser 700 through an electrode pattern or wire wiring.

The second EA modulator section 105 includes: the n-type electrode 32 of the second EA modulator formed on the n-type InGaAsP second conductive layer 21e and electrically connected to the n-type InGaAsP second conductive layer 21e; and the p-type electrode 42 of the second EA modulator formed on the p-type InGaAs second contact layer 23f and electrically connected to the p-type InGaAs second contact layer 23f. The n-type electrode 32 of the second EA modulator is electrically connected to a wire bonding pad 53 for the n-type electrode of the second EA modulator formed on the surface of the optical modulator integrated semiconductor laser 700 through an electrode pattern or wire wiring.

A common electrode 45 is formed on the surface of the optical modulator integrated semiconductor laser 700. The common electrode 45 is electrically connected to the n-type electrode 31 of the first EA modulator and the p-type electrode 42 of the second EA modulator through an electrode pattern or wire wiring. In Embodiment 3, the common electrode 45 itself is also formed by an electrode pattern or wire wiring.

The features of the optical modulator integrated semiconductor laser 700, which is an example of the semiconductor optical integrated device according to Embodiment 3, will be described below.

In the optical modulator integrated semiconductor laser 700, the width of the first EA modulator section 103 in the direction perpendicular to the optical waveguide direction is set to be larger than the width of the second EA modulator section 105 in the direction perpendicular to the optical waveguide direction. That is, the width of the first EA modulator Wd1, which is the width of the first EA modulator section 103, is set to be larger than the width of the second EA modulator Wd2, which is the width of the second EA modulator section 105. In other words, the width of the second EA modulator Wd2 is smaller than the width of the first EA modulator Wd1.

By making the width of the first EA modulator Wd1 of the first EA modulator section 103 larger than the width of the second EA modulator Wd2 of the second EA modulator section 105, the resistances Rp1 and Rn1 of the first EA modulator section 103 become smaller. As a result, the voltage drop Iph1×(Rp1+Rn1) in the first EA modulator section 103 is reduced, thus providing an effect of improving the extinction ratio, wavelength chirp, and modulation bandwidth of the semiconductor optical integrated device.

Furthermore, the thermal resistance of the first EA modulator section 103 is reduced, thus providing an effect that the temperature difference between the first EA modulator section 103 and the second EA modulator section 105 caused by the difference in the light absorption amount is alleviated. As a result, the temperature of the first EA modulator section 103 is lower than that of the conventional structure, thus providing an effect of reducing the photocurrent Iph1 of the first EA modulator section 103.

The width of the second connecting waveguide section 104 connecting the first EA modulator section 103 and the second EA modulator section 105 in the direction perpendicular to the optical waveguide direction, that is, the width Wc2 of the second connection waveguide gradually changes from the width Wd1 of the first EA modulator on the first EA modulator section 103 side to the width Wd2 of the second EA modulator on the second EA modulator section 105 side.

As an example of the change in the width Wc2 of the second connection waveguide, as shown in FIG. 7, it is preferable that the second connecting waveguide section 104 has a tapered waveguide 62 which monotonically decreases from the width Wd1 of the first EA modulator on the first EA modulator section 103 side to the width Wd2 of the second EA modulator on the second EA modulator section 105 side.

FIGS. 9 and 10 are schematic views for explaining the operation of an optical modulator integrated semiconductor laser 700 which is an example of a semiconductor optical integrated device according to Embodiment 3.

As shown in FIG. 9, when the EA modulator section itself is a tapered waveguide, the width changes in the EA modulator section, thereby the center of the transverse mode of the guided light is absorbed by the EA modulator section, so that the light intensity at both left and right ends of the EA modulator section becomes relatively large. When the transverse mode changes in such a state, a problem that the scattering loss of light increases occurs.

On the other hand, as shown in FIG. 10, in the case of the optical modulator integrated semiconductor laser 700, which is an example of the semiconductor optical integrated device according to Embodiment 3, the widths of the first EA modulator section 103 and the second EA modulator section 105 are kept constant so that the transverse mode is not changed, and thus the width is changed only in the second connecting waveguide section 104, thereby achieving the effect of avoiding an increase in light scattering loss.

That is, the region where the waveguide width changes may be limited to the portion of the tapered waveguide 62 of the second connecting waveguide section 104 between the first EA modulator section 103 and the second EA modulator section 105.

### Effects of Embodiment 3

In the semiconductor optical integrated device according to Embodiment 3, the width of the first EA modulator section is set to be larger than the width of the second EA modulator section and the waveguide width of the second connecting waveguide section connecting the first EA modulator section and the second EA modulator section is changed, thus providing an effect of improving the extinction ratio, wavelength chirp, and modulation bandwidth of the semiconductor optical integrated device.

### Embodiment 4

### Configuration of Optical Modulator Integrated Semiconductor Laser According to Embodiment 4

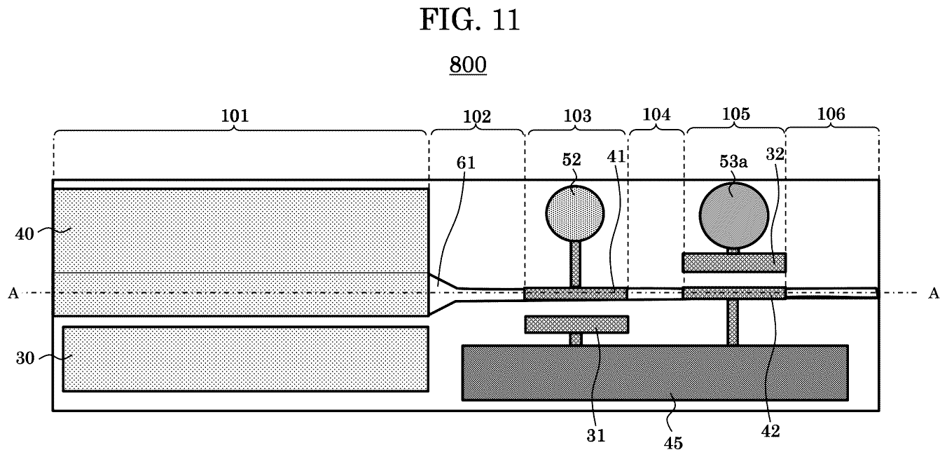

FIG. 11 is a top view of a device structure of an optical modulator integrated semiconductor laser 800 which is an example of a semiconductor optical integrated device according to Embodiment 4.

The optical modulator integrated semiconductor laser 800 which is an example of a semiconductor optical integrated device according to Embodiment 4 differs from the optical modulator integrated semiconductor laser 500 which is an example of a semiconductor optical integrated device according to Embodiment 1 shown in FIG. 2 in that the area SP2 of the wire bonding pad 53a for the n-type electrode of the second EA modulator is larger than the area SP1 of the wire bonding pad 52 for the p-type electrode of the first EA modulator, and the waveguide lens section 106 is provided, and the other configuration is the same as that of Embodiment 1. Note that the semiconductor laser section 101 and the waveguide lens section 106 may be removed from the optical modulator integrated semiconductor laser 800 to form an integrated optical modulator.

Since the photocurrent Iph1 of the first EA modulator section 103 is larger than the photocurrent Iph2 of the second EA modulator section 105, the DC bias voltage of the first EA modulator section 103 is smaller than the DC bias voltage of the second EA modulator section 105. That is, the DC bias voltage applied to the first EA modulator section 103 shifts toward zero V. As a result, the frequency bandwidth of the first EA modulator section 103 becomes smaller than that of the second EA modulator section 105. Such phenomenon causes deterioration of the modulation waveform.

In the configuration of the semiconductor optical integrated device according to Embodiment 4, by making the area SP1 of the wire bonding pad 52 for the p-type electrode of the first EA modulator smaller than the area SP2 of the wire bonding pad 53a for the n-type electrode of the second EA modulator, the electrical capacitance incident on the first EA modulator section 103 can be reduced. As a result, the frequency bandwidth of the first EA modulator section 103 can be adjusted equally to that of the second EA modulator section 105, thus providing an effect that the degradation of the modulation waveform of the semiconductor optical integrated device can be prevented.

Note that not only the area of the wire bonding pad 52 for the p-type electrode of the first EA modulator, but also the area of the p-type electrode 41 of the first EA modulator, the area of the electrode lead, and the like may be reduced.

### Effects of Embodiment 4

In the semiconductor optical integrated device according to Embodiment 4, the area of the wire bonding pad for the n-type electrode of the second EA modulator is set to be larger than the area of the wire bonding pad for the p-type electrode of the first EA modulator, thus providing an effect that the degradation of the modulation waveform can be prevented.

In Embodiments other than Embodiment 4, making the length of the first EA modulator section 103 shorter than the length of the second EA modulator section 105 enables the frequency bandwidth of the first EA modulator section 103 to be adjusted to be equal to the frequency bandwidth of the second EA modulator section 105.

In contrast, according to Patent Document 1, in an optical modulator integrated semiconductor laser electrically connected to the n-type electrode of the first EA modulator and the p-type electrode of the second EA modulator, even if the intensity of the light passing through the first EA modulator section is fluctuated by electromagnetic interference, the light emitted from the optical modulator integrated semiconductor laser is not affected by electromagnetic interference because the second EA modulator cancels the fluctuation of the light intensity. The cancellation effect of the fluctuation of the light intensity becomes maximum when the extinction ratios of the first EA modulator section and the second EA modulator section are the same.

However, since the photocurrent Iph1 flowing through the first EA modulator section 103 is larger than the photocurrent Iph2 flowing through the second EA modulator section 105, the voltage amplitude VEA1 becomes smaller than the voltage amplitude VEA2, and thus the extinction ratio of the first EA modulator section 103 becomes smaller than the extinction ratio of the second EA modulator section 105. Therefore, making the length of the first EA modulator section 103 longer than the length of the second EA modulator section 105 enables the extinction ratio of both sections to be equal and the cancellation effect of the light intensity fluctuations to be increased. The size of the length of the first EA modulator section 103 and the second EA modulator section 105 may be determined depending on whether the effect of the adjustment of the frequency bandwidth or the cancellation effect of the fluctuation of the light intensity is given priority.

### Embodiment 5

### Configuration of Optical Module According to Embodiment 5

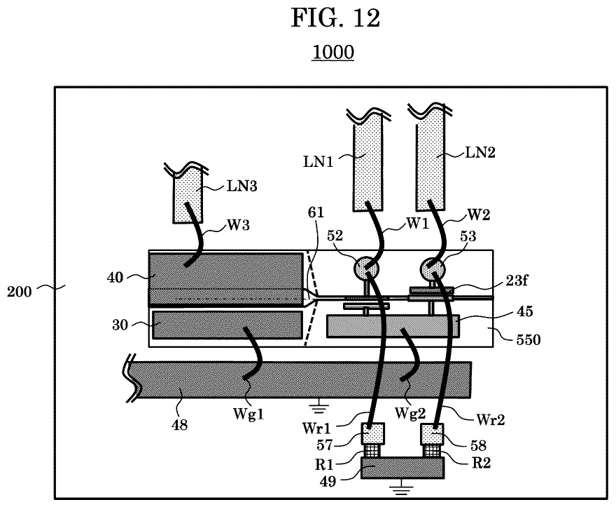

FIG. 12 is a top view of an optical module 1000 according to Embodiment 5. The optical module 1000 according to Embodiment 5 includes, as a configuration of the optical module 1000, the arrangement of each electrode of the optical modulator integrated semiconductor laser 550 according to Embodiment 5 and the connection of signal lines and ground lines with wires.

Specifically, in the optical module 1000 according to Embodiment 5, the optical modulator integrated semiconductor laser 550 is arranged on a mounting substrate 200, and each wire bonding pad on the optical modulator integrated semiconductor laser 550 and each terminating resistor and the like arranged on the mounting substrate 200 are electrically connected through wires made of metal. The optical modulator integrated semiconductor laser 550 has a configuration in which a waveguide lens section 106 is provided in addition to the configuration of the optical modulator integrated semiconductor laser 500 according to Embodiment 1.

In the optical module 1000 according to Embodiment 5, the mounting substrate 200 on which the optical modulator integrated semiconductor laser 550 is mounted is a substrate made of aluminum nitride, which is also called a sub-mount. But this is not limited thereto, and the mounting substrate 200 may be made of other materials, or the mounting substrate 200 may be a configuration in which the optical modulator integrated semiconductor laser 550 once mounted on the sub-mount is secondarily mounted on another mounting substrate.

Components such as a first modulation signal line LN1, a second modulation signal line LN2, a semiconductor laser section current line LN3, a grounding electrode 48, a first terminating resistor R1, and a second terminating resistor R2 are arranged on the mounting substrate 200. The grounding electrode 48 is not necessarily required to be zero V with respect to the ground, but may be short-circuited with the ground plane at high-frequency through a large capacitor. In the present disclosure, wiring, wiring patterns, electrodes, electrode patterns, and the like are collectively referred to as lines.

The p-type electrode 40 of the semiconductor laser section is electrically connected to the semiconductor laser section current line LN3 through a wire W3, and the n-type electrode 30 of the semiconductor laser section is electrically connected to the grounding electrode 48 through a wire Wg1.

The p-type electrode 41 of the first EA modulator in the first EA modulator section 103 is electrically connected to the first modulation signal line LN1 through a wire W1 through the wire bonding pad 52 for the p-type electrode of the first EA modulator. The wire bonding pad 52 for the p-type electrode of the first EA modulator is electrically connected to a wire bonding pad 57 for the terminating resistor through a wire Wr1. The wire bonding pad 57 is electrically connected to one end of the first terminating resistor R1.

The n-type electrode 32 of the second EA modulator in the second EA modulator section 105 is electrically connected to the second modulation signal line LN2 through a wire W2 through the wire bonding pad 53 for the n-type electrode of the second EA modulator. The wire bonding pad 53 for the n-type electrode of the second EA modulator is electrically connected to a wire bonding pad 58 for the terminating resistor through a wire Wr2, and is also electrically connected to one end of the second terminating resistor R2.

The other end of the first terminating resistor R1 and the other end of the second terminating resistor R2 are electrically connected to a grounding electrode 49.

The common electrode 45 is electrically connected to the n-type electrode 31 of the first EA modulator and the p-type electrode 42 of the second EA modulator through an electrode pattern or wire wiring. The common electrode 45 is electrically connected to the grounding electrode 48 through a wire Wg2.

In the above description, the case of electrical connection between the electrode and the wire bonding pad by wire is exemplified. However, the optical modulator integrated semiconductor laser 550 may be mounted on the mounting substrate 200 or the like with a junction down, that is, the upper surface of the chip as the lower side, and electrically connected to each wiring pattern and each electrode of the optical modulator integrated semiconductor laser 550 by solder or gold ball.

In the optical module 1000 according to Embodiment 3 shown in FIG. 12, the common electrode 45, to which the n-type electrode 30 of the semiconductor laser section, the n-type electrode 31 of the first EA modulator, and the p-type electrode 42 of the second EA modulator are electrically connected, is formed on the same side with the optical waveguide of the optical modulator integrated semiconductor laser 550 as a reference. In the following description, the line along the optical waveguide of the optical modulator integrated semiconductor laser 550 is referred to as a reference line. That is, the semiconductor laser section 101, the first connecting waveguide section 102, the first EA modulator section 103, the second connecting waveguide section 104, the second EA modulator section 105, and the waveguide lens section 106, which constitute the optical modulator integrated semiconductor laser 550, are sequentially arranged on the reference line along the optical waveguide.

In the case of the optical module 1000 according to Embodiment 5 shown in FIG. 12, the n-type electrode 30 of the semiconductor laser section, the n-type electrode 31 of the first EA modulator, and the first common electrode 45 are formed on the side of the grounding electrode 48 with respect to the reference line. The n-type electrode 30 of the semiconductor laser section and the grounding electrode 48 are electrically connected through the wire Wg1. The common electrode 45, to which the n-type electrode 31 of the first EA modulator and the p-type electrode 42 of the second EA modulator are electrically connected, is electrically connected to the grounding electrode 48 through the wire Wg2.

If electromagnetic waves radiated from the first modulation signal line LN1 and the second modulation signal line LN2 interfere with each wire that electrically connects the semiconductor laser section 101 comprising the DFB laser and each EA modulator section to the grounding electrode 48, an intensity noise may be superimposed on the optical modulation signals.

First, the wire Wg2, which electrically connects the common electrode 45 and the grounding electrode 48, is required to be as short as possible to enable the EA modulator to operate at high speed. This can be achieved by locating the grounding electrode 48 close to each EA modulator.

Next, in order to reduce electromagnetic waves radiated from the first modulation signal line LN1 and the second modulation signal line LN2, and also for high-speed operation, it is important to shorten the lengths of the wire W1, W2 as much as possible. For this purpose, the first modulation signal line LN1 and the second modulation signal line LN2 are required to be routed as close as possible to each EA modulator section of the optical modulator integrated semiconductor laser 550.

Here, if the grounding electrode 48, the first modulation signal line LN1, and the second modulation signal line LN2 are arranged on the same side with respect to the reference line, the first modulation signal line LN1 and the second modulation signal line LN2 need to be located apart from each EA modulator by the size of the grounding electrode 48. In addition, since the distance between the wires W1, W2 and the wire Wg2 is close, the electromagnetic interference tends to occur.

Conversely, if the grounding electrode 48 is arranged on the opposite side of the first modulation signal line LN1 and the second modulation signal line LN2 with respect to the reference line, the first modulation signal line LN1 and the second modulation signal line LN2 can be arranged closer to each EA modulator, and the distance between the wires W1, W2 and the wire Wg2 can be separated, thereby the electromagnetic interference is less likely to occur than if they are arranged on the same side. That is, it is preferable that the grounding electrode 48 is arranged on the opposite side of the first modulation signal line LN1 and the second modulation signal line LN2 with respect to the reference line.

The characteristic configuration of the optical module 1000 according to Embodiment 5 will be described below. Normally, the output impedance of the driver driving the EA modulator section is 50 Ω, and the resistance value of the terminating resistor connected to the driver is generally equal to the output impedance of the driver. In addition, when the output impedance of the driver is not 50 Ω, the terminating resistor is generally set to 50 Ω.

When the terminating resistor connected to the driver is increased, the load impedance when viewed from the driver, that is, the impedance of the EA modulator and the terminating resistor, also increases, and the voltage amplitude applied to the EA modulator section increases, especially in the low-frequency range.

In contrast, the load impedance in the high-frequency range is dominated by the decrease in impedance caused by the capacitance of the EA modulator section which is arranged in parallel with the terminating resistor. As a result, the effect of the terminating resistor value decreases, and thus the effect of the increase in the voltage amplitude decreases. Therefore, the frequency bandwidth deteriorates. That is, as the resistance value of the terminating resistor becomes smaller, the frequency response becomes flatter. As a countermeasure against the above-mentioned problem, the optical module 1000 according to Embodiment 5 is set such that the resistance value of the first terminating resistor R1 is larger than the resistance value of the second terminating resistor R2.

As described in Embodiment 1, the voltage amplitude VEA1 applied to the first modulation layer 22 of the first EA modulator section 103 is smaller than the voltage amplitude VEA2 applied to the second modulation layer 22a of the second EA modulator section 105. When the configuration of the optical module 1000 according to Embodiment 5 is applied, the resistance value of the first terminating resistor R1 is set to be larger than the resistance value of the second terminating resistor R2, thereby the voltage amplitude VEA1 applied to the first modulation layer 22 of the first EA modulator section 103 becomes larger. As a result, the difference between the voltage amplitude VEA1 applied to the first EA modulator section 103 and the voltage amplitude VEA2 applied to the second EA modulator section 105 is reduced. Therefore, the voltage amplitude VEA1 applied to the first EA modulator section 103 and the voltage amplitude VEA2 applied to the second EA modulator section 105 can both approach the optimum value.

Applying the configuration of the optical module 1000 according to Embodiment 5 enables an increase in the extinction ratio of the optical module and improvement of the modulation waveform thereof. The first terminating resistor R1 and the second terminating resistor R2 are preferably set to resistance values close to the output impedance of the driver.

In order to achieve a sufficient effect in the above-described configuration, it is preferable that the resistance value of the first terminating resistor R1 is set to be 5% or more greater than the resistance value of the second terminating resistor R2, and it is further preferable to set it to be 10% or more greater.

### Effects of Embodiment 5

As described above, in the optical module according to Embodiment 5, the resistance value of the first terminating resistor R1 is set to be larger than the resistance value of the second terminating resistor R2, thus providing an effect that the extinction ratio of the optical module can be increased and the modulation waveform thereof can be improved.

### Modification of Embodiment 5

### Configuration of Optical Module According to Modification of Embodiment 5

The optical module according to Modification of Embodiment 5 differs from the optical module 1000 according to Embodiment 5 in that the resistance value of the first terminating resistor R1 is set to be larger than the resistance value of the second terminating resistor R2 in the optical module 1000 according to Embodiment 5, while the resistance value of the first terminating resistor R1 is set to be smaller than the resistance value of the second terminating resistor R2 in the optical module according to Modification of Embodiment 5.

Reducing the first terminating resistor R1 connected to the first EA modulator section 103, where the modulation bandwidth becomes narrower, enables the frequency bandwidth of the first EA modulator section 103 to be made closer to the frequency bandwidth of the second EA modulator section 105. As a result, the difference between the voltage amplitude VEA1 applied to the first EA modulator section 103 and the voltage amplitude VEA2 applied to the second EA modulator section 105 is reduced, and thus the modulation waveform is improved.

In addition, the voltage amplitude in the low-frequency range of the first EA modulator section 103 is reduced. As a result, the amount of wavelength chirping of the optical module can be reduced by reducing the amount of light change in the first EA modulator section 103 where the DC bias voltage is relatively positive and the α parameter is relatively large, and by increasing the amount of light change in the second EA modulator section 105 where the DC bias voltage is relatively negative and the α parameter is relatively small.

In order to achieve a sufficient effect in the above-described configuration, it is preferable that the resistance value of the first terminating resistor R1 is set to be 5% or more smaller than the resistance value of the second terminating resistor R2, and it is further preferable to set it to be 10% or more smaller.

### Effects of Modification of Embodiment 5

As described above, in the optical module according to the Modification of Embodiment 5, the resistance value of the first terminating resistor R1 is set to be smaller than the resistance value of the second terminating resistor R2, thus providing an effect that reducing the amount of wavelength chirping in the optical module can be achieved.

### Embodiment 6

### Structure of Optical Module According to Embodiment 6

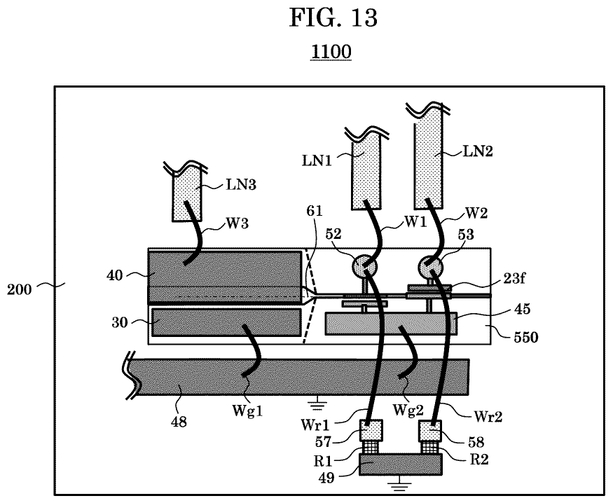

FIG. 13 is a top view of a device structure of an optical module 1100 according to Embodiment 6. The sum of the length of the first modulation signal line LN1 that transmits the first modulation signal S1 for modulating the first EA modulator section 103 and the length of the wire W1 that electrically connects the first modulation signal line LN1 and the wire bonding pad 52 for the p-type electrode of the first EA modulator is defined as the length of the first line Li1. The sum of the length of the second modulation signal line LN2 that transmits the second modulation signal S2 for modulating the second EA modulator section 105 and the length of the wire W2 that electrically connects the second modulation signal line LN2 and the wire bonding pad 53 for the n-type electrode of the second EA modulator is defined as the length of the first line Li2.

The optical module 1100 according to Embodiment 6 is characterized in that the length of the second line Li2 is set longer than the length of the first line Li1.

Applying the configuration of the optical module 1100 according to Embodiment 6, the modulation bandwidth of the first EA modulator section 103 becomes relatively larger than that of the second EA modulator section 105. As a result, the modulation bandwidth difference between the first EA modulator section 103 and the second EA modulator section 105 is alleviated.

In the above-described configuration, it is preferable to set the length of the second line Li2 to be at least 15% longer than the length of the first line Li1, and it is further preferable to set it to be 30% or more longer than the length of the first line Li1.

### Effects of Embodiment 6

As described above, in the optical module according to the Embodiment 6, the length of the second line Li2 is set longer than the length of the first line Li1, thus providing an effect of alleviating the modulation bandwidth difference between the first EA modulator section and the second EA modulator section.

### Embodiment 7

### Configuration of Optical Module According to Embodiment 7

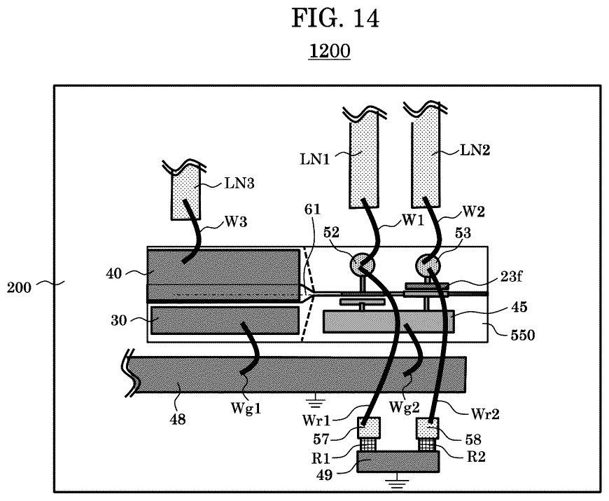

FIG. 14 is a top view of a device structure of an optical module 1200 according to Embodiment 7.

The optical module 1200 according to Embodiment 7 is characterized in that the length of the wire Wr1 electrically connecting the wire bonding pad 52 for the p-type electrode of the first EA modulator and the first terminating resistor R1 is set to be longer than the length of the wire Wr2 electrically connecting the wire bonding pad 53 for the n-type electrode of the second EA modulator and the second terminating resistor R2.

Applying the configuration of the optical module 1200 according to Embodiment 7, the modulation bandwidth of the first EA modulator section 103 becomes relatively larger than that of the second EA modulator section 105. As a result, the modulation bandwidth difference between the first EA modulator section 103 and the second EA modulator section 105 is alleviated.

In the above-described configuration, it is preferable to set the length of the wire Wr1 to be at least 15% longer than the length of the wire Wr2, and it is further preferable to set it to be 30% or more longer than the length of the wire Wr2.

### Effects of Embodiment 7

As described above, in the optical module according to the Embodiment 7, the length of the wire Wr1 is set longer than the length of the wire Wr2, thus providing an effect of alleviating the modulation bandwidth difference between the first EA modulator section and the second EA modulator section.

### Embodiment 8

### Configuration of Multi-Level Intensity Modulation Transceiver According to Embodiment 8

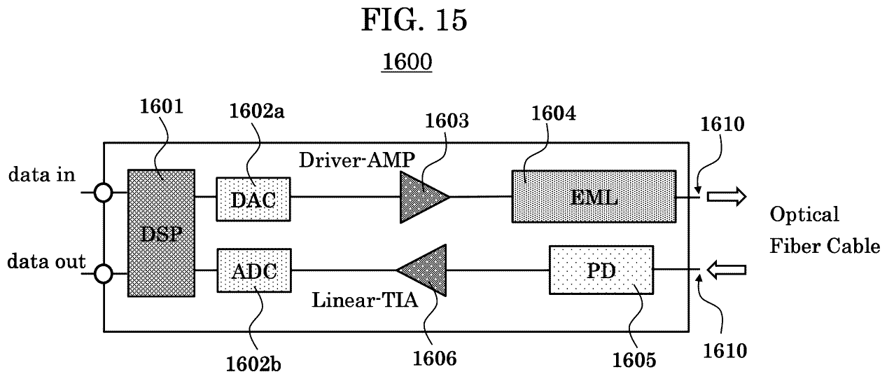

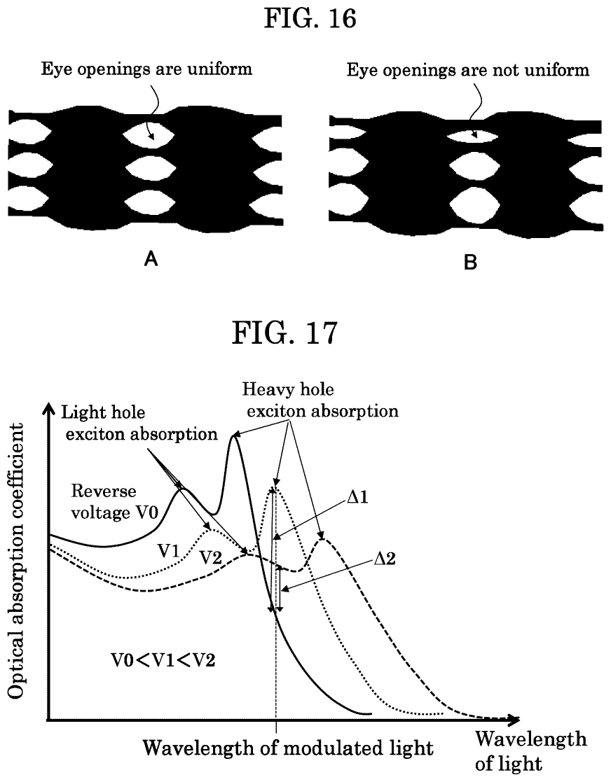

FIG. 15 is a schematic diagram of a configuration of a multi-level intensity modulation transceiver 1600 according to Embodiment 8. FIG. 16 is a conceptual diagram showing the received waveform of the multi-level intensity modulation transceiver 1600 according to Embodiment 8.

The multi-level intensity modulation transceiver 1600 according to Embodiment 8 is a multi-level intensity modulation transceiver of the PAM (Pulse Amplitude Modulation) system which is a multi-level intensity modulation system. In a transmitting unit, a digital signal generated by a DSP (Digital Signal Processor) 1601, which is a digital signal processing circuit, is analog-converted by a DAC (Digital-to-Analog Converter) 1602a, then amplified by the Driver-AMP 1603, and an optical signal are emitted to an optical fiber cable 1610 through the optical system by driving an optical modulator integrated semiconductor laser 1604.

In a receiving unit, the optical signal is inputted from the optical fiber cable 1610 through the optical system to the PD (Photodiode) 1605, which is a semiconductor light receiving device, and then converts and multiplies the optical signal into a current. Furthermore, after the optical signal is amplified by a Linear-TIA (Trans Impedance Amplifier) 1606, the optical signal is converted into digital signal by the ADC (Analog-to-Digital Converter) 1602b, and then the digital signal is processed by the DSP 1601.

The optical modulator integrated semiconductor laser 1604 according to Embodiment 8 is the optical modulator integrated semiconductor laser includes: the semiconductor laser section 101; the first connecting waveguide section 102; the first EA modulator section 103; the second connecting waveguide section 104; the second EA modulator section 105, and the waveguide lens section 106 as described in Embodiments 3 and 4. Note that the waveguide lens section 106 is not an essential component of the optical modulator integrated semiconductor laser 1604.

In FIG. 15, only one wavelength configuration (one set) is described, but in the multi-level intensity modulation transceiver 1600, four or eight wavelength multiplexing is usually performed, so that four or eight sets of multi-level intensity modulation transceivers 1600 are mounted at high-density.

### Operation of Multi-Level Intensity Modulation Transceiver According to Embodiment 8

In the multi-level intensity modulation transceiver 1600 of the PAM system as shown in FIG. 15, it is necessary to receive not only binary signals of one and zero, such as NRZ (None Return to Zero) and RZ (Return to Zero), but also, for example, four values with different optical signal intensities in the PAM4.

A conceptual diagram of the received waveform of PAM4 is shown in A of FIG. 16. An index called TDECQ (Transmitter Dispersion and Eye Closure Quaternary) is used to determine whether the received waveform is good or bad in the case of PAM4. TDECQ is calculated by the following Expression (8).

$$TDECQ ( dB ) = 10 \times log ( OMA / ( 6 \times Qt \times R ) ) \qquad ( 8 )$$

In Expression (8), the optical modulation amplitude (OMA) is the total amplitude from level zero to level three, Qt is a value that depends on the SER (Symbol Error Rate) specified by IEEE (Institute of Electrical and Electronics Engineers), and R is an additional noise value required to achieve the SER value. TDECQ (dB) is specified to be, for example, 3 dB or less.

In order to reduce TDEQ (dB), the following conditions are required.
(1) Condition A: The eye aperture of each level is large and uniform.
(2) Condition B: The noise of each level is small.

In order for the eye aperture of each level consisting of four values with different signal intensities of light under Condition A to be uniform, the linearity of the optical modulator integrated semiconductor laser 1604 as the transmission light source is required to be excellent. Here, the excellent linearity of the optical modulator integrated semiconductor laser 1604 means that the following Expression (9) is satisfied, when the change in the applied voltage to the EA modulator is denoted by ΔV and the amount of fluctuating light transmitted through the EA modulator is denoted by ΔP.

$$Δ P / Δ V = constant \qquad ( 9 )$$

Furthermore, since the PAM4 modulates with four values, the dynamic range is required to be excellent. Here, the excellent dynamic range means that the relationship in Expression (9) is maintained even when the change in the applied voltage, that is, the voltage amplitude ΔV, is increased to 0.5 V, 1.0 V, 1.5 V, for example. As shown in the receiving waveform B in FIG. 16, which is a conceptual diagram showing the received waveform of the multi-level intensity modulation transceiver 1600, when the linearity and dynamic range deteriorate, the eye aperture formed between the level two and the level three deteriorates.

FIG. 17 shows a conceptual diagram of the wavelength dependence of the optical absorption coefficient in the case where voltage is applied to the MQW layer constituting the modulation layer of the EA modulator section. As shown in FIG. 17, when voltage is applied to the EA modulator, the exciton absorption wavelength of the MQW layer shifts toward longer wavelengths, and thus the absorption coefficient at longer wavelengths increases. That is, the EA modulator utilizes the quantum confinement Stark effect to extinguish light.

However, when the reverse voltage V0 is increased to V1 at the wavelength of the modulated light 80, the amount of change Δ1 in the optical absorption coefficient increases, but when the reverse voltage is further increased to V2, the amount of change Δ2 in the optical absorption coefficient decreases. That is, the extinction ratio depending on the amount of change in the optical absorption coefficient decreases when the reverse voltage is too high. Therefore, there is an optimum range for the modulation voltage amplitude Vq, and the linearity is better when Vq is as small as possible.

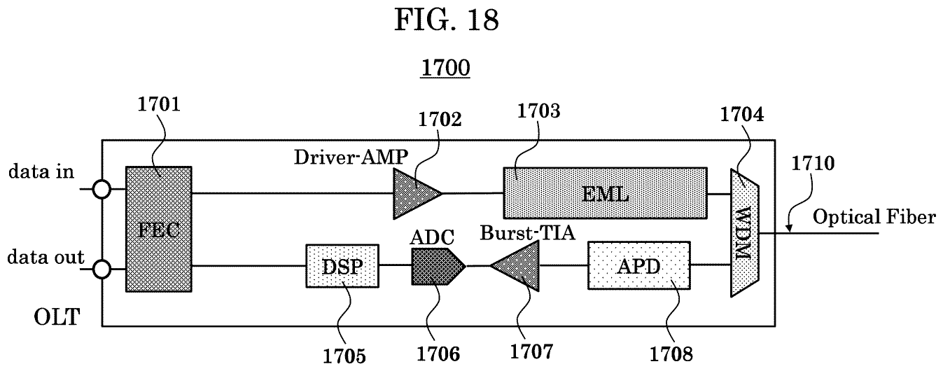

As shown in Embodiments 3 and 4, in the optical modulator integrated semiconductor laser 1604 according to the present disclosure, the two EA modulators are operated with single-phase voltage signals, thereby a high extinction ratio can be obtained, and the modulation voltage amplitude Vq of each EA modulator can be reduced, resulting in excellent linearity. Therefore, the eye aperture becomes uniform as shown in A of FIG. 18, which is a conceptual diagram showing the received waveform of the multi-level intensity modulation transceiver 1600.

In order to reduce the noise at each level of Condition B, it is necessary to cancel out the fluctuation of the amount of transmitted light of the first EA modulator section 103 due to the electromagnetic interference using the second EA modulator section 105. The optical modulator integrated semiconductor laser 1604 according to the present disclosure has excellent linearity because the modulation voltage amplitude Vq can be reduced as described above.

In the optical modulator integrated semiconductor laser 500 shown in the schematic diagram of FIG. 1, it is assumed that electromagnetic waves of the same magnitude are simultaneously applied to the first modulation signal line LN1 and the second modulation signal line LN2, and the DC bias voltage of the first EA modulator section 103 changes by +ΔV, and the DC bias voltage of the second EA modulator section 105 changes by −ΔV. The changes in the amount of transmitted light of the first EA modulator section 103 and the second EA modulator section 105 in this case are assumed to be +ΔP1 and −ΔP2, respectively. If the linearity is poor and the extinction amount of the EA modulator decreases as the reverse voltage increases, then ΔP1>ΔP2. As a result, the fluctuating light intensity ΔP after passing through the two EA modulators fluctuates by the amount expressed in the following Expression (10).

$$Δ P = Δ P 1 - Δ P 2 \qquad ( 10 )$$

In order for the fluctuation light intensity ΔP to be zero, the following Expression (11) is required to be satisfied.

$$Δ P 1 / Δ V = Δ P 2 / Δ V \qquad ( 11 )$$

As described above, since the modulation voltage amplitude Vq can be reduced in the present disclosure, linearity is excellent as expressed by Expression (11). Therefore, the effect of canceling out electromagnetic interference is high.

### Effects of Embodiment 8

As described above, in the multi-level intensity modulation transceiver according to Embodiment 8, the optical modulator integrated semiconductor laser according to Embodiments 3 and 4 is used as a light source of the multi-level intensity modulation transceiver, thereby linearity of the optical output is excellent and the fluctuation of the transmitted light amount due to electromagnetic interference is small. Therefore, in multi-level intensity modulation such as PAM4, a modulation waveform with uniform eye aperture at each level and small noise can be achieved. As a result, TDECQ, which is an index of the waveform quality, is improved, thus providing an effect of achieving a multi-level intensity modulation transceiver that enables broadening of the optical transceiver, high-density mounting, and simplification of the error rate correction circuit.

### Embodiment 9

### Configuration of Optical Line Terminating Device According to Embodiment 9

FIG. 18 is a schematic diagram showing an optical line terminating device (OLT) 1700 on the station side of a 50G-PON system according to Embodiment 9. The optical line terminating device 1700 according to Embodiment 9 converts input data into a modulation signal using an optical modulator integrated semiconductor laser 1703 according to the present disclosure through a FEC (Forward Error Correction) 1701 and a driver amplifier 1702. The modulation signal pass through an WDM (Wavelength Division Multiplexing) 1704 and the optical system, and is coupled to an optical fiber cable 1710.

The modulation signal transmitted by the optical fiber cable 1710 is converted into a current signal by a semiconductor photodetector such as an APD 1708 (Avalanche Photodiode) or a PD through the optical system and the WDM 1704. The current signal passes through a burst TIA (Trans Impedance Amplifier) 1707, an ADC 1706, which is an analog/digital conversion circuit, and a DSP 1705, which is a digital signal processing circuit, and then is corrected by a FEC 1701 to output the data.

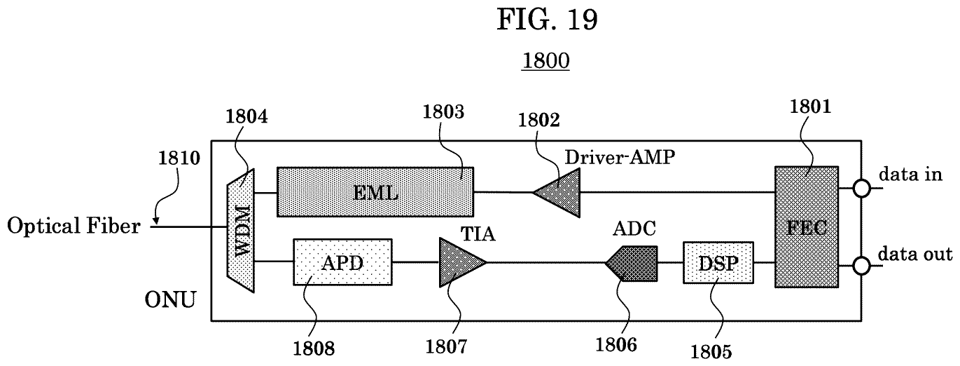

FIG. 19 is a schematic diagram showing the optical line terminating device (ONU) 1800 on a subscriber side of the 50G-PON system according to Embodiment 9. The optical line terminating device 1800 according to Embodiment 9 converts input data into an optical modulation signal using the optical modulator integrated semiconductor laser 1803 through a FEC 1801 and a driver amplifier 1802. The optical modulation signal pass through a WDM 1804 and the optical system, and is coupled to the optical fiber cable 1810.

The optical modulation signal transmitted from the optical fiber cable 1810 are converted into a current signal by a photodetector such as an APD 1808 or a PD through the optical system and the WDM 1804. The current signal passes through the TIA 1807, the ADC 1806, which is an analog/digital conversion circuit, and a DSP 1805, which is a digital signal processing circuit, and then is corrected for errors in the FEC 1801 and the data is output.

The optical modulator integrated semiconductor laser 1703, 1803 according to Embodiment 9 is the optical modulator integrated semiconductor laser comprising the semiconductor laser section 101, the first connecting waveguide section 102, the first EA modulator section 103, the second connecting waveguide section 104, the second EA modulator section 105, and the waveguide lens section 106 as described in Embodiments 3 and 4. Note that the waveguide lens section 106 is not an essential component of the optical modulator integrated semiconductor lasers 1703, 1803.

### Action of Optical Line Terminating Device According to Embodiment 9

As shown in FIGS. 18 and 19, electronic circuits such as the DSP and the FEC that perform signal processing at high-speed are mounted on the OLT and the ONU. In particular, since broadband signal processing is required in the next generation 50G-PON, electromagnetic interference may occur in the OLT and the ONU. As described in Embodiments 3 and 4, in the optical modulator integrated semiconductor laser according to the present disclosure, the electromagnetic interference is canceled by the first EA modulator section 103 and the second EA modulator section 105, so that the signal error rate does not deteriorate. Therefore, the circuit configuration of the FEC, which corrects the signal error, and the DSP, which reduces the influence of the noise, can be simplified, thus providing an effect of reducing the power consumption.

### Effects of Embodiment 9

As described above, in the optical line terminating device according to Embodiment 9, the optical modulator integrated semiconductor laser of the present disclosure is used as a light source, thus providing an effect of obtaining a station-side optical line terminating device (OLT) and a subscriber-side optical line terminating device (ONU) that are capable of broadband communication and has low power consumption.

Although the disclosure is described above in terms of various exemplary embodiments and implementations, it should be understood that the various features, aspects, and functionality described in one or more of the individual embodiments are not limited in their applicability to the particular embodiment with which they are described, but instead can be applied, alone or in various combinations to one or more of the embodiments of the disclosure.

It is therefore understood that numerous modifications which have not been exemplified can be devised without departing from the scope of the present disclosure. For example, at least one of the constituent components may be modified, added, or eliminated. At least one of the constituent components mentioned in at least one of the preferred embodiments may be selected and combined with the constituent components mentioned in another preferred embodiment.

### DESCRIPTION OF THE REFERENCE CHARACTERS

1 semi-insulating substrate
1a Fe-doped InP substrate
2 n-type cladding layer
2a n-type InGaAsP conductive layer
2b n-type InP cladding layer
3 active layer
4 p-type cladding layer
4a p-type InP cladding layer
4b p-type InGaAs contact layer
5 insulating protection film
6 current blocking layer
11, 11b first lower cladding layer
11a, 11c second lower cladding layer
11d InP third lower cladding layer
12, 12b first waveguide layer
12a, 12c second waveguide layer
12d InGaAsP third waveguide layer
13, 13b first upper cladding layer
13a, 13c second upper cladding layer
13d InP third upper cladding layer
21 n-type first semiconductor layer
21a n-type second semiconductor layer
21c n-type InGaAsP first conductive layer
21d n-type InP first cladding layer
21e n-type InGaAsP second conductive layer
21f n-type InP second cladding layer
22 first modulation layer
22a second modulation layer
23 p-type first semiconductor layer
23a p-type second semiconductor layer
23c p-type InP first cladding layer
23d p-type InGaAs first contact layer
23e p-type InP second cladding layer
23f p-type InGaAs second contact layer
30 n-type electrode of semiconductor laser section
31 n-type electrode of first EA modulator
32 n-type electrode of second EA modulator
40 p-type electrode of semiconductor laser section
41 p-type electrode of first EA modulator
42 p-type electrode of second EA modulator
45 common electrode
48, 49 grounding electrode
52 wire bonding pad for p-type electrode of first EA modulator
53, 53a wire bonding pad for n-type electrode of second EA modulator
61 waveguide conversion section
80 modulated light
101 semiconductor laser section
102 first connecting waveguide section
103 first EA modulator section
104 second connecting waveguide section
105 second EA modulator section
106 waveguide lens section
200 mounting substrate
500, 550, 700, 800, 1604, 1703, 1803 optical modulator integrated semiconductor laser
600 integrated optical modulator
1000, 1100, 1200 optical module
1600 multi-level intensity modulation transceiver
1601, 1705, 1805 DSP
1602a, 1602b ADC
1603, 1702, 1802 driver amplifier
1610, 1710, 1810 optical fiber cable
1605 PD
1606 linear-TIA
1700, 1800 optical line terminating device
1701, 1801 FEC
1704, 1804 WDM
1706, 1806 ADC
1707 burst TIA
1708, 1808 APD
1807 TIA
LN1 first modulation signal line
LN2 second modulation signal line
LN3 semiconductor laser section current line
R1 first terminating resistor
R2 second terminating resistor
S1 first modulation signal
S2 second modulation signal
W1, W2, W3, Wg1, Wg2 wire

What is claimed is:

1. A method for driving a semiconductor optical integrated device comprising at least a first EA modulator section having an n-type first semiconductor layer, a first modulation layer, and a p-type first semiconductor layer and a second EA modulator section having an n-type second semiconductor layer, a second modulation layer, and a p-type second semiconductor layer, the first EA modulator section and the second EA modulator section being provided on a substrate along an optical waveguide direction, the n-type first semiconductor layer and the p-type second semiconductor layer being electrically connected, wherein
an absolute value of a DC bias voltage Vp1 applied to the first EA modulator section is larger than an absolute value of a DC bias voltage Vp2 applied to the second EA modulator section.

2. The method for driving a semiconductor optical integrated device according to claim 1, the semiconductor optical integrated device further comprising a semiconductor laser section formed on the substrate, wherein
laser light emitted from the semiconductor laser section is incident on the first EA modulator section.

3. The method for driving a semiconductor optical integrated device according to claim 1, wherein
the absolute value of the DC bias voltage Vp1 applied to the first EA modulator section is smaller than three times the absolute value of the DC bias voltage Vp2 applied to the second EA modulator section.

4. A semiconductor optical integrated device comprising:
a substrate;
a first EA modulator section formed on the substrate and comprising at least an n-type first semiconductor layer, a first modulation layer, and a p-type first semiconductor layer; and
a second EA modulator section formed on the substrate and comprising at least an n-type second semiconductor layer, a second modulation layer having a width smaller than a width of the first modulation layer, and a p-type second semiconductor layer electrically connected to the n-type first semiconductor layer.

5. The semiconductor optical integrated device according to claim 4 further comprising a semiconductor laser section formed on the substrate, wherein
laser light emitted from the semiconductor laser section is incident on the first EA modulator section.

6. The semiconductor optical integrated device according to claim 4 further comprising a connecting waveguide section formed on the substrate between the first EA modulator section and the second EA modulator section and comprising at least a lower cladding layer, a waveguide layer, and an upper cladding layer, wherein
the waveguide width of the connecting waveguide section gradually decreases from the first EA modulator section to the second EA modulator section.

7. A semiconductor optical integrated device comprising:
a substrate;
a first EA modulator section formed on the substrate and comprising at least an n-type first semiconductor layer, a first modulation layer, and a p-type first semiconductor layer;
a second EA modulator section formed on the substrate and comprising at least an n-type second semiconductor layer, a second modulation layer, and a p-type second semiconductor layer electrically connected to the n-type first semiconductor layer;
a common electrode electrically connecting an n-type electrode of a first EA modulator electrically connected to the n-type first semiconductor layer, and a p-type electrode of a second EA modulator electrically connected to the p-type second semiconductor layer;
a wire bonding pad for a p-type electrode of the first EA modulator electrically connected to the p-type electrode of the first EA modulator connected to the p-type first semiconductor layer; and
a wire bonding pad for an n-type electrode of the second EA modulator electrically connected the n-type electrode of the second EA modulator connected to the n-type second semiconductor layer and having an area larger than an area of the wire bonding pad for the p-type electrode of the first EA modulator.

8. The semiconductor optical integrated device according to claim 7, wherein
the area of the wire bonding pad for the n-type electrode of the second EA modulator is smaller than two times the area of the wire bonding pad for the p-type electrode of the first EA modulator.

9. A semiconductor optical integrated device comprising:
a substrate;
a first EA modulator section formed on the substrate and comprising at least an n-type first semiconductor layer, a first modulation layer, and a p-type first semiconductor layer;
a second EA modulator section formed on the substrate and comprising at least an n-type second semiconductor layer, a second modulation layer, and a p-type second semiconductor layer electrically connected to the n-type first semiconductor layer; and
a common electrode electrically connecting an n-type electrode of a first EA modulator electrically connected to the n-type first semiconductor layer, and a p-type electrode of a second EA modulator electrically connected to the p-type second semiconductor layer, wherein
the length of the first EA modulator section is shorter than the length of the second EA modulator section.

10. A semiconductor optical integrated device comprising:
a substrate;
a first EA modulator section formed on the substrate and comprising at least an n-type first semiconductor layer, a first modulation layer, and a p-type first semiconductor layer;
a second EA modulator section formed on the substrate and comprising at least an n-type second semiconductor layer, a second modulation layer, and a p-type second semiconductor layer electrically connected to the n-type first semiconductor layer; and
a common electrode electrically connecting an n-type electrode of a first EA modulator electrically connected to the n-type first semiconductor layer, and a p-type electrode of a second EA modulator electrically connected to the p-type second semiconductor layer, wherein
the length of the first EA modulator section is longer than the length of the second EA modulator section.

11. An optical module comprising:
a mounting substrate;
a semiconductor optical integrated device mounted on the mounting substrate, the semiconductor optical integrated device including: a substrate; a first EA modulator section formed on the substrate and comprising at least an n-type first semiconductor layer, a first modulation layer, and a p-type first semiconductor layer; a second EA modulator section formed on the substrate and comprising at least an n-type second semiconductor layer, a second modulation layer, and a p-type second semiconductor layer electrically connected to the n-type first semiconductor layer; a wire bonding pad for a p-type electrode of a first EA modulator electrically connected to the p-type first semiconductor layer; and a wire bonding pad for an n-type electrode of a second EA modulator electrically connected to the n-type electrode of the second EA modulator electrically connected to the n-type second semiconductor layer;
a first modulation signal line LN1 provided on the mounting substrate and electrically connected to the wire bonding pad for the p-type electrode of the first EA modulator through a wire;
a second modulation signal line LN2 provided on the mounting substrate and electrically connected to the wire bonding pad for the n-type electrode of the second EA modulator through a wire;
a first terminating resistor electrically connected to the wire bonding pad for the p-type electrode of the first EA modulator; and
a second terminating resistor electrically connected to the wire bonding pad for the n-type electrode of the second EA modulator and having a resistance value different from the first terminating resistor.

12. The optical module according to claim 11, wherein
the resistance value of the first terminating resistor is larger than the resistance value of the second terminating resistor.

13. The optical module according to claim 11, wherein
the resistance value of the first terminating resistor is smaller than the resistance value of the second terminating resistor.

14. An optical module comprising:
a mounting substrate;
a semiconductor optical integrated device mounted on the mounting substrate, the semiconductor optical integrated device including: a substrate; a first EA modulator section formed on the substrate and comprising at least an n-type first semiconductor layer, a first modulation layer, and a p-type first semiconductor layer; a second EA modulator section formed on the substrate and comprising at least an n-type second semiconductor layer, a second modulation layer, and a p-type second semiconductor layer electrically connected to the n-type first semiconductor layer; a wire bonding pad for a p-type electrode of a first EA modulator electrically connected to the p-type first semiconductor layer; and a wire bonding pad for an n-type electrode of a second EA modulator electrically connected to the n-type electrode of the second EA modulator electrically connected to the n-type second semiconductor layer;
a first modulation signal line LN1 provided on the mounting substrate and electrically connected to the wire bonding pad for the p-type electrode of the first EA modulator through a wire; and
a second modulation signal line LN2 provided on the mounting substrate and electrically connected to the wire bonding pad for the n-type electrode of the second EA modulator through a wire, wherein
the sum of the length of the second modulation signal line LN2 and the length of the wire W2 is longer than the sum of the length of the first modulation signal line LN1 and the length of the wire W1.

15. An optical module comprising:
a mounting substrate;
a semiconductor optical integrated device mounted on the mounting substrate, the semiconductor optical integrated device including: a substrate; a first EA modulator section formed on the substrate and comprising at least an n-type first semiconductor layer, a first modulation layer, and a p-type first semiconductor layer; a second EA modulator section formed on the substrate and comprising at least an n-type second semiconductor layer, a second modulation layer, and a p-type second semiconductor layer electrically connected to the n-type first semiconductor layer; a wire bonding pad for a p-type electrode of a first EA modulator electrically connected to the p-type first semiconductor layer; and a wire bonding pad for an n-type electrode of a second EA modulator electrically connected to the n-type electrode of the second EA modulator electrically connected to the n-type second semiconductor layer;
a first modulation signal line LN1 provided on the mounting substrate and electrically connected to the wire bonding pad for the p-type electrode of the first EA modulator through a wire W1;
a second modulation signal line LN2 provided on the mounting substrate and electrically connected to the wire bonding pad for the n-type electrode of the second EA modulator through a wire W2;
a first terminating resistor electrically connected to the wire bonding pad for the p-type electrode of the first EA modulator through a wire Wr1; and
a second terminating resistor electrically connected to the wire bonding pad for the n-type electrode of the second EA modulator through a wire Wr2 shorter in length than the wire Wr1.

16. The optical module according to claim 11, wherein
the first modulation signal line LN1 and the second modulation signal line LN2 are arranged on the same side as the wire bonding pad for the p-type electrode of the first EA modulator and the wire bonding pad for the n-type electrode of the second EA modulator with respect to a reference line along the center of the semiconductor optical integrated device, with the semiconductor optical integrated device as a reference.

17. The optical module according to claim 11, wherein
the first terminating resistor and the second terminating resistor are arranged on the opposite side of the wire bonding pad for the p-type electrode of the first EA modulator and the wire bonding pad for the n-type electrode of the second EA modulator with respect to a reference line along the center of the semiconductor optical integrated device, with the semiconductor optical integrated device as a reference.

18. The optical module according to claim 11 further comprising a common electrode electrically connecting the n-type electrode of the first EA modulator electrically connected to the n-type first semiconductor layer and the p-type electrode of the second EA modulator electrically connected to the p-type second semiconductor layer.

19. A multi-level intensity modulation transceiver comprising:
a digital signal processing circuit for generating a multi-level intensity modulated digital signal on a basis of an input data signal;
an analog-to-digital conversion circuit for converting the digital signal into an analog modulation signal;
an amplifier circuit for amplifying the analog modulation signal;
the semiconductor optical integrated device according to claim 4 for inputting the amplified analog modulation signal; and
an optical system for coupling a modulation signal emitted from the semiconductor optical integrated device to an optical fiber.

20. An optical line terminating device comprising:
a forward error correction circuit for correcting a data error on a basis of an input data signal;
an amplifier circuit for amplifying an electric signal;
the semiconductor optical integrated device according to claim 4 for receiving the amplified electric signal; and
an optical system for coupling a modulation signal emitted from the semiconductor optical integrated device to an optical fiber.

21. A multi-level intensity modulation transceiver comprising:
a digital signal processing circuit for generating a multi-level intensity modulated digital signal on a basis of an input data signal;
an analog-to-digital conversion circuit for converting the digital signal into an analog modulation signal;
an amplifier circuit for amplifying the analog modulation signal;
the semiconductor optical integrated device according to claim 7 for inputting the amplified analog modulation signal; and
an optical system for coupling a modulation signal emitted from the semiconductor optical integrated device to an optical fiber.

22. An optical line terminating device comprising:
a forward error correction circuit for correcting a data error on a basis of an input data signal;
an amplifier circuit for amplifying an electric signal;
the semiconductor optical integrated device according to claim 7 for receiving the amplified electric signal; and
an optical system for coupling a modulation signal emitted from the semiconductor optical integrated device to an optical fiber.
